(19) United States
(12) Patent Application Publication
(10) Pub. No.: US 2012/0200808 A1
(43) Pub. Date: Aug. 9, 2012

(54) Polymer compound and polymer light emitting device

(75) Inventors: Takakazu Yamamoto, Yokohama (JP); Choi Bongjin, Busan (KR); Takeaki Koizumi, Yokohama (JP); Isao Yamaguchi, Matsue (JP); Osamu Goto, Tsukuba (JP); Makoto Anryu, Tsukuba (JP)

(73) Assignees: TOKYO INSTITUTE OF TECHNOLOGY, Tokyo (JP); SUMITOMO CHEMICAL COMPANY, LIMITED, Tokyo (JP)

(21) Appl. No.: 11/599,440

(22) Filed: Nov. 15, 2006

(30) Foreign Application Priority Data
Nov. 16, 2005 (JP) 2005-331801

(51) Int. Cl. G02F 1/13357; C08G 73/02; H01L 51/54; C09K 11/06; B05D 5/06; C08G 61/02; C07F 5/02

(52) U.S. Cl. 349/69; 528/8; 525/540; 564/11; 252/301.35; 427/66; 257/40; 257/E51.026

(57) ABSTRACT

To provide a polymer compound which is useful as a light emitting material or charge transport material having a boron atom.

A polymer compound comprising a structure represented by a formula (1) as described below:

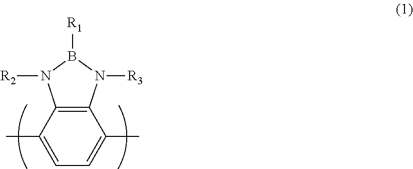

wherein R₁, R₂, and R₃ each independently represents a hydrogen atom or a substituent.

### BACKGROUND OF THE INVENTION

(1) Field of the Invention

The present invention relates to a polymer compound and a polymer light emitting device (hereinafter, sometimes referred to as a polymer LED).

(2) Description of Related Art

Various kinds of light emitting materials and charge transport materials, which is solvent-soluble and have high molecular weights, have been investigated because of their ability to form an organic layer on a light emitting device by the use of a coating method. As an example of such materials, a polymer compound having a structure described below has been known (the structure has a repeating unit in which two benzene rings are condensed with a cyclopentadiene ring) (see Non-patent Document 1 and Patent Document 1, for example).

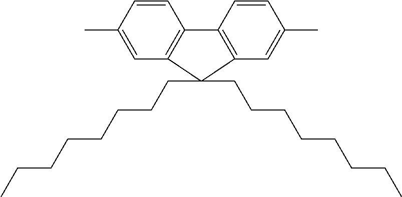

Non-patent Document 1: Advanced Materials, 1997, Vol. 9, No. 10, p. 798
Patent Document 1: WO99/54385

### SUMMARY OF THE INVENTION

A boron atom has a high electron affinity, so that an organic EL material containing the boron atom has been expected to develop an enhanced property. However, examples of the light emitting device having the boron atom are limited because such compounds as having the boron atoms provide a common property which is frequently unstable against air and humidity.

An object of the present invention is to provide a polymer compound which is useful as a light emitting material or charge transport material having a boron atom.

That is, the present invention is intended to provide a polymer compound which contains a structure, as described in the following formula (1):

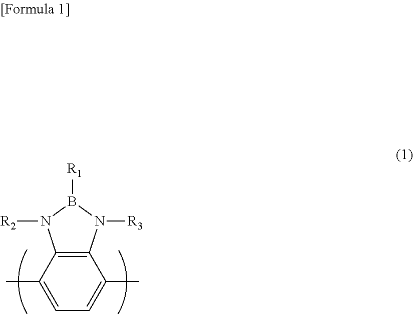

wherein R₁, R₂, and R₃ each independently represents a hydrogen atom or a substituent.

The polymer compound of the present invention contains a boron atom, and is useful as a light-emitting material or a charge transporting material. Since the polymer compound of the present invention as an organic EL material can emit a light with high intensity at a shorter wavelength and have high levels of charge injection and transport, the polymer LED comprising the polymer compound of the present invention can be used as a carved or planar-shaped light source for a backlight of liquid crystal display or an illumination lamp, and also can be used for a segment type of display device and a dot matrix type of flat panel display, etc.

### DETAILED DESCRIPTION OF THE INVENTION

A polymer compound according to the present invention comprises a structure which is expressed by the above described formula (1).

Among the polymer compounds of the present invention, a compound which includes a structure represented by the above described formula (1) as a repeating unit is preferable.

In the above described formula (1), substituents represented by R₁, R₂, and R₃ are preferably selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group.

The alkyl group may be any of linear, branched, and cyclic groups, typically having a carbon number of about 1 to 20, preferably 1 to 10, and specific examples thereof include a methyl group, ethyl group, propyl group, isopropyl group, butyl group, isobutyl group, t-butyl group, pentyl group, isoamyl group, hexyl group, cyclohexyl group, heptyl group, octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, perfluorooctyl group.

The alkoxy group may be any of linear, branched, and cyclic groups, and may also have a substituent(s). It typically has a carbon number of about 1 to 20, and specific examples thereof include a methoxy group, ethoxy group, propyloxy group, isopropyloxy group, butoxy group, isobutoxy group, t-butoxy group, pentyloxy group, hexyloxy group, cyclohexyloxy group, heptyloxy group, octyloxy group, 2-ethylhexyloxy group, nonyloxy group, decyloxy group, 3,7-dimethyloctyloxy group, lauryloxy group, trifluoromethoxy group, pentafluoroethoxy group, perfluorobutoxy group, perfluorohexyloxy group, perfluorooctyloxy group, methoxymethyloxy group, and 2-methoxyethyloxy group.

The alkylthio group may be any of linear, branched, and cyclic groups, and may also have a substituent(s). It typically has a carbon number of about 1 to 20, and specific examples thereof include a methylthio group, ethylthio group, propylthio group, isopropylthio group, butylthio group, isobutylthio group, t-butylthio group, pentylthio group, hexylthio group, cyclohexylthio group, heptylthio group, octylthio group, 2-ethylhexylthio group, nonylthio group, decylthio group, 3,7-dimethyloctylthio group, laurylthio group, and trifluoromethylthio group.

The aryl group is an atomic group obtained by removing one hydrogen atom from an aromatic hydrocarbon, and includes an atomic group having a condensed ring and an atomic group in which two or more separate benzene rings or condensed rings are linked to each other directly or via a group such as vinylene. The aryl group typically has a carbon number of about 6 to 60, preferably 7 to 48, and specific examples thereof include a phenyl group, a C₁-C₁₂ alkoxyphenyl group (C₁-C₁₂ represents a carbon number of 1 to 12. The same applies hereafter.), a C₁-C₁₂ alkylphenyl group, 1-naphthyl group, 2-naphthyl group, 1-anthracenyl group, 2-anthracenyl group, 9-anthracenyl group, and pentafluorophenyl group, and a phenyl group, C₁-C₁₂ alkoxyphenyl group, and C₁-C₁₂ alkylphenyl group are preferable. Specific examples of C₁-C₁₂ alkoxy include methoxy, ethoxy, propyloxy, isopropyloxy, butoxy, isobutoxy, t-butoxy, pentyloxy, hexyloxy, cyclohexyloxy, heptyloxy, octyloxy, 2-ethylhexyloxy, nonyloxy, decyloxy, 3,7-dimethyloctyloxy, and lauryloxy.

Specific examples of the C₁-C₁₂ alkylphenyl group include a methylphenyl group, ethylphenyl group, dimethylphenyl group, propylphenyl group, mesityl group, methylethylphenyl group, isopropylphenyl group, butylphenyl group, isobutylphenyl group, t-butylphenyl group, pentylphenyl group, isoamylphenyl group, hexylphenyl group, heptylphenyl group, octylphenyl group, nonylphenyl group, decylphenyl group, and dodecylphenyl group.

The aryloxy group typically has a carbon number of about 6 to 60, and preferably 7 to 48, and specific examples thereof include a phenoxy group, C₁-C₁₂ alkoxyphenoxy group, C₁-C₁₂ alkylphenoxy group, 1-naphthyloxy group, 2-naphthyloxy group, and pentafluorophenyloxy group, and a C₁-C₁₂ alkoxyphenoxy group and C₁-C₁₂ alkylphenoxy group are preferable.

Specific examples of the C₁-C₁₂ alkoxy include methoxy, ethoxy, propyloxy, isopropyloxy, butoxy, isobutoxy, t-butoxy, pentyloxy, hexyloxy, cyclohexyloxy, heptyloxy, octyloxy, 2-ethylhexyloxy, nonyloxy, decyloxy, 3,7-dimethyloctyloxy, and lauryloxy.

Specific examples of the C₁-C₁₂ alkylphenoxy group include a methylphenoxy group, ethylphenoxy group, dimethylphenoxy group, propylphenoxy group, trimethylphenoxy group, methylethylphenoxy group, isopropylphenoxy group, butylphenoxy group, isobutylphenoxy group, t-butylphenoxy group, pentylphenoxy group, isoamylphenoxy group, hexylphenoxy group, heptylphenoxy group, octylphenoxy group, nonylphenoxy group, decylphenoxy group, and dodecylphenoxy group.

The arylthio group may have a substituent(s) on the aromatic ring, and typically a carbon number of about 3 to 60, and specific examples thereof include a phenylthio group, C₁-C₁₂ alkoxyphenylthio group, C₁-C₁₂ alkylphenylthio group, 1-naphthylthio group, 2-naphthylthio group, pentafluorophenylthio group, pyridylthio group, pyridazinylthio group, pyrimidylthio group, pyrazylthio group, and triazylthio group.

The arylalkyl group may have a substituent(s), and typically a carbon number of about 7 to 60, and specific examples thereof include a phenyl-C₁-C₁₂ alkyl group, C₁-C₁₂ alkoxyphenyl-C₁-C₁₂ alkyl group, C₁-C₁₂ alkylphenyl-C₁-C₁₂ alkyl group, 1-naphthyl-C₁-C₁₂ alkyl group, and 2-naphthyl-C₁-C₁₂ alkyl group.

The arylalkoxy group may have a substituent(s), and typically a carbon number of about 7 to 60, and specific examples thereof include a phenyl-C₁-C₁₂ alkoxy group, C₁-C₁₂ alkoxyphenyl-C₁-C₁₂ alkoxy group, C₁-C₁₂ alkylphenyl-C₁-C₁₂ alkoxy group, 1-naphthyl-C₁-C₁₂ alkoxy group, and 2-naphthyl-C₁-C₁₂ alkoxy group.

The arylalkylthio group may have a substituent(s), and typically carbon number of about 7 to 60, and specific examples thereof include a phenyl-C₁-C₁₂ alkylthio group, C₁-C₁₂ alkoxyphenyl-C₁-C₁₂ alkylthio group, C₁-C₁₂ alkylphenyl-C₁-C₁₂ alkylthio group, 1-naphthyl-C₁-C₁₂ alkylthio group, and 2-naphthyl-C₁-C₁₂ alkylthio group.

The arylalkenyl group typically has a carbon number of about 8 to 60, and specific examples thereof include a phenyl-C₂-C₁₂ alkenyl group, C₁-C₁₂ alkoxyphenyl-C₂-C₁₂ alkenyl group, C₁-C₁₂ alkylphenyl-C₂-C₁₂ alkenyl group, 1-naphthyl-C₂-C₁₂ alkenyl group, and 2-naphthyl-C₂-C₁₂ alkenyl group, and a C₁-C₁₂ alkoxyphenyl-C₂-C₁₂ alkenyl group and C₂-C₁₂ alkylphenyl-C₁-C₁₂ alkenyl group are preferable.

The arylalkynyl group typically has a carbon number of about 8 to 60, and specific examples thereof include a phenyl-C₂-C₁₂ alkynyl group, C₁-C₁₂ alkoxyphenyl-C₂-C₁₂ alkynyl group, C₁-C₁₂ alkylphenyl-C₂-C₁₂ alkynyl group, 1-naphthyl-C₂-C₁₂ alkynyl group, and 2-naphthyl-C₂-C₁₂ alkynyl group, and a C₁-C₁₂ alkoxyphenyl-C₂-C₁₂ alkynyl group and C₁-C₁₂ alkylphenyl-C₂-C₁₂ alkynyl group are preferable.

The substituted amino group includes an amino group substituted by 1 or 2 groups selected from an alkyl group, an aryl group, an arylalkyl group, and a monovalent heterocyclic group, where the alkyl group, the aryl group, the arylalkyl group, or the monovalent heterocyclic group may also have a substituent(s). The substituted amino group typically has a carbon number of about 1 to 60 excluding the carbon number of the above described substituent(s), and preferably 2 to 48.

Specific examples thereof include a methylamino group, dimethylamino group, ethylamino group, diethylamino group, propylamino group, dipropylamino group, isopropylamino group, diisopropylamino group, butylamino group, isobutylamino group, t-butylamino group, pentylamino group, hexylamino group, cyclohexylamino group, heptylamino group, octylamino group, 2-ethylhexylamino group, nonylamino group, decylamino group, 3,7-dimethyloctylamino group, laurylamino group, cyclopentylamino group, dicyclopentylamino group, cyclohexylamino group, dicyclohexylamino group, pyrrolidyl group, piperidyl group, ditrifluoromethylamino group, phenylamino group, diphenylamino group, C₁-C₁₂ alkoxyphenylamino group, di(C₁-C₁₂ alkoxyphenyl)amino group, di(C₁-C₁₂ alkylphenyl)amino group, 1-naphthylamino group, 2-naphthylamino group, pentafluorophenylamino group, pyridylamino group, pyridazinylamino group, pyrimidylamino group, pyrazylamino group, triazylamino group, phenyl-C₁-C₁₂ alkylamino group, C₁-C₁₂ alkoxyphenyl-C₁-C₁₂ alkylamino group, C₁-C₁₂ alkylphenyl-C₁-C₁₂ alkylamino group, di (C₁-C₁₂ alkoxyphenyl-C₁-C₁₂ alkyl)amino group, di (C₁-C₁₂ alkylphenyl-C₁-C₁₂ alkyl)amino group, 1-naphthyl-C₁-C₁₂ alkylamino group, and 2-naphthyl-C₁-C₁₂ alkylamino group.

The substituted silyl group includes a silyl group substituted by 1, 2, or 3 groups selected from an alkyl group, an aryl group, an arylalkyl group, and a monovalent heterocyclic group. The substituted silyl group typically has a carbon number of about 1 to 60, and preferably 3 to 48. The alkyl group, the aryl group, the arylalkyl group, or the monovalent heterocyclic group may also have a substituent(s).

Specific examples thereof include a trimethylsilyl group, triethylsilyl group, tripropylsilyl group, tri-isopropylsilyl group, dimethyl-isopropylsilyl group, diethyl-isopropylsilyl group, t-butylsilyldimethylsilyl group, pentyldimethylsilyl group, hexyldimethylsilyl group, heptyldimethylsilyl group, octyldimethylsilyl group, 2-ethylhexyl-dimethylsilyl group, nonyldimethylsilyl group, decyldimethylsilyl group, 3,7-dimethyloctyl-dimethylsilyl group, lauryldimethylsilyl group, phenyl-C₁-C₁₂ alkylsilyl group, C₁-C₁₂ alkoxyphenyl-C₁-C₁₂ alkylsilyl group, C₁-C₁₂ alkylphenyl-C₁-C₁₂ alkylsilyl group, 1-naphthyl-C₁-C₁₂ alkylsilyl group, 2-naphthyl-C₁-C₁₂ alkylsilyl group, phenyl-C₁-C₁₂ alkyldimethylsilyl group, triphenylsilyl group, tri-p-xylylsilyl group, tribenzylsilyl group, diphenylmethylsilyl group, t-butyldiphenylsilyl group, and dimethylphenylsilyl group.

The halogen atom includes a fluorine atom, a chlorine atom, a bromine atom, and an iodine atom.

The acyl group typically has a carbon number of about 2 to 20, preferably 2 to 18, and specific examples thereof include an acetyl group, propionyl group, butyryl group, isobutyryl group, pivaloyl group, benzoyl group, trifluoroacetyl group, and pentafluorobenzoyl group.

The acyloxy group typically has a carbon number of about 2 to 20, preferably 2 to 18, and specific examples thereof include an acetoxy group, propionyloxy group, butyryloxy group, isobutyryloxy group, pivaloyloxy group, benzoyloxy group, trifluoroacetyloxy group, and pentafluorobenzoyloxy group.

The imine residue has a carbon number of about 2 to 20, preferably 2 to 18, and specific examples thereof are groups represented by the following structural formulas.

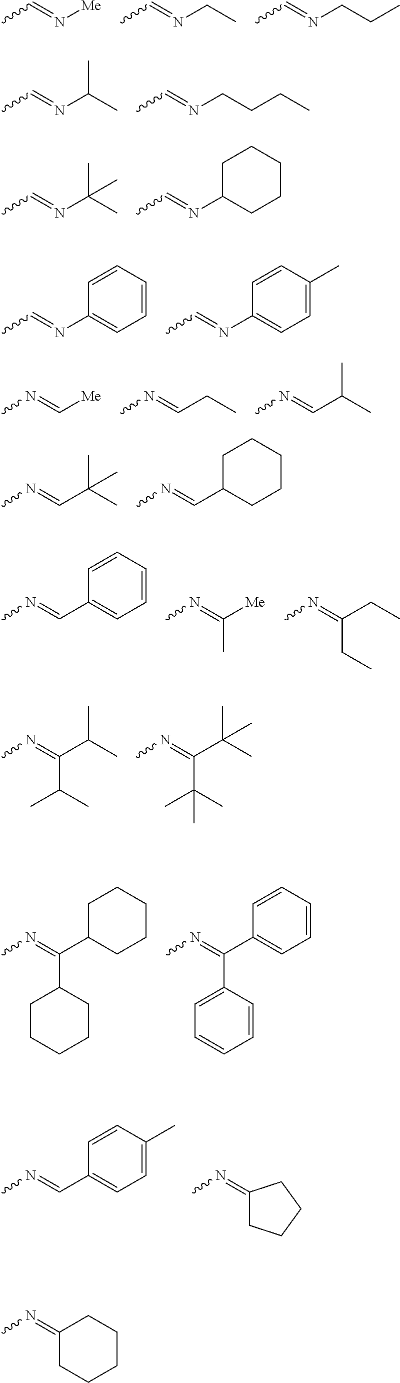

The amide group typically has a carbon number of about 2 to 20, preferably 2 to 18, and specific examples thereof include a formamide group, acetamide group, propionamide group, butyramide group, benzamide group, trifluoroacetamide group, pentafluorobenzamide group, diformamide group, diacetamide group, a dipropionamide group, dibutyramide group, dibenzamide group, ditrifluoroacetamide group, and dipentafluorobenzamide group.

The acid imide group is a residue formed by removing a hydrogen atom from the nitrogen atom of an acid imide, and has a carbon number of about 4 to 20, and specific examples thereof are groups as described below.

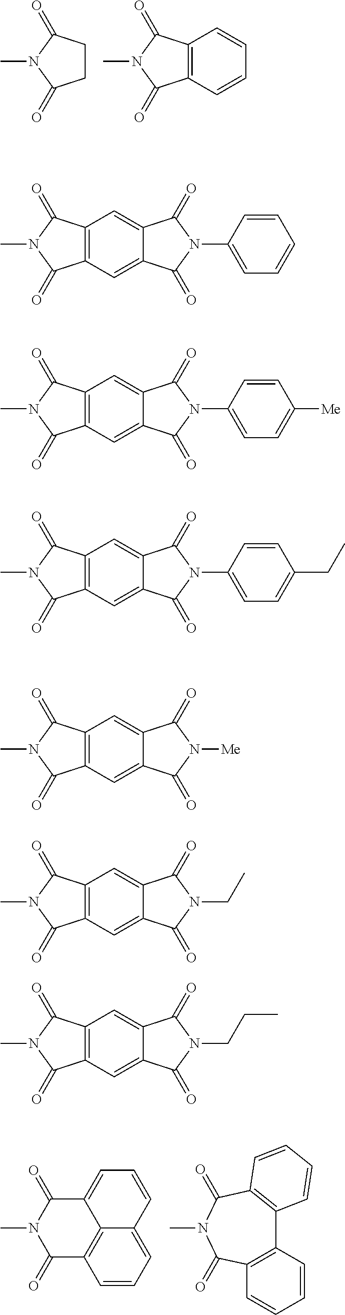

The monovalent heterocyclic group means an atomic group obtained by removing one hydrogen atom from a heterocyclic compound, and typically has a carbon number of about 4 to 60, preferably 4 to 20. It should be noted that the carbon number of the heterocyclic group does not include the carbon number of the substituent(s). The heterocyclic compound means an organic compound having a cyclic structure, in which the ring member elements comprise not only a carbon atom but also a hetero atom such as oxygen, sulfur, nitrogen, phosphorous, boron and/or the like. Specific examples thereof include a thienyl group, C₁-C₁₂ alkylthienyl group, pyrrolyl group, furyl group, pyridyl group, C₁-C₁₂ alkylpyridyl group, piperidyl group, quinolyl group, and isoquinolyl group, and a thienyl group, C₁-C₁₂ alkylthienyl group, pyridyl group, and C₁-C₁₂ alkylpyridyl group are preferable.

The substituted carboxyl group means a carboxyl group substituted with an alkyl group, an aryl group, an arylalkyl group, or a monovalent heterocyclic group, and typically has a carbon number of about 2 to 60, preferably 2 to 48, and specific examples thereof include a methoxycarbonyl group, ethoxycarbonyl group, propoxycarbonyl group, isopropoxycarbonyl group, butoxycarbonyl group, isobutoxycarbonyl group, t-butoxycarbonyl group, pentyloxycarbonyl group, hexyloxycarbonyl group, cyclohexyloxycarbonyl group, heptyloxycarbonyl group, octyloxycarbonyl group, 2-ethylhexyloxycarbonyl group, nonyloxycarbonyl group, decyloxycarbonyl group, 3,7-dimethyloctyloxycarbonyl group, dodecyloxycarbonyl group, trifluoromethoxycarbonyl group, pentafluoroethoxycarbonyl group, perfluorobutoxycarbonyl group, perfluorohexyloxycarbonyl group, perfluorooctyloxycarbonyl group, phenoxycarbonyl group, naphthoxycarbonyl group, and pyridyloxycarbonyl group. The alkyl group, the aryl group, the arylalkyl group, or the monovalent heterocyclic group may also have a substituent(s). The carbon number of the substituted carboxyl group does not include the carbon number of the substitutent(s).

The total number of the repeating unit represented by the above described formula (1) typically represents 1 mol % or more and 100 mol % or less, and preferably 10 mol % or more and 90 mol % or less of the total number of all the repeating units contained in the polymer compound used for the present invention.

The total amount of the repeating unit represented by (1) is preferably 50 mol % or less when the polymer compound used for the present invention is used as the light-emitting material, and is preferably 30 mol % or more when used as the charge injection/transporting material.

The polymer compound according to the present invention can include other repeating units than the above described formula (1), and examples thereof include repeating units represented by the following formulas (5), (6), (7), or (8).

—Ar₁— (5)

—(—Ar₂—X₁—)_{ff}—Ar₃— (6)

—Ar₄—X₂— (7)

—X₃— (8)

(In the above formulas, Ar₁, Ar₂, Ar₃, and Ar₄ each independently represent an arylene group, a divalent heterocyclic group, or a divalent group having a metal complex structure. X₁, X₂, and X₃ each independently represent —CR₉═CR₂₀—, —C≡C—, —N(R₁₁)—, or —(SiR₁₂R₁₃)ₘ—. R₉ and R₁₀ each independently represent a hydrogen atom, an alkyl group, an aryl group, a monovalent heterocyclic group, a carboxyl group, a substituted carboxyl group, or a cyano group. R₁₁, R₁₂, and R₁₃ each independently represent a hydrogen atom, an alkyl group, an aryl group, a monovalent heterocyclic group, an arylalkyl group, or a substituted amino group. ff represents 1 or 2. m represents an integer from 1 to 12. When each of R₉, R₁₀, R₁₁, R₁₂, and R₁₃ is present in a plural number, they may be or may not be the same.)

The arylene group described above is an atomic group obtained by removing two hydrogen atoms from an aromatic hydrocarbon, and thus includes an atomic group having a condensed ring and also an atomic group in which two or more separate benzene rings or condensed rings are linked to each other directly or via a group such as vinylene. The arylene group may also have a substituent(s).

The substituents include an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group.

The arylene group, from which the substituent(s) is excluded, typically has a carbon number of about 6 to 60 and preferably 6 to 20. In addition, the total carbon number of the arylene group including such substituents is usually about 6 to 100.

Specific examples of the arylene group include a phenylene group (e.g., the following formulas 1 to 3), a naphthalenediyl group (the following formulas 4 to 13), an anthracene-diyl group (the following formulas 14 to 19), a biphenyl-diyl group (the following formulas 20 to 25), a fluorene-diyl group (the following formulas 36 to 38), a terphenyl-diyl group (the following formulas 26 to 28), a condensed ring compound group (the following formulas 29 to 35), a stilbene-diyl (the following formulas D-1 to D-4), a distilbene-diyl (the following formulas E and F), and the like. Among others, the phenylene group, the biphenylene group, the fluorene-diyl group, and the stilbene-diyl group are preferable.

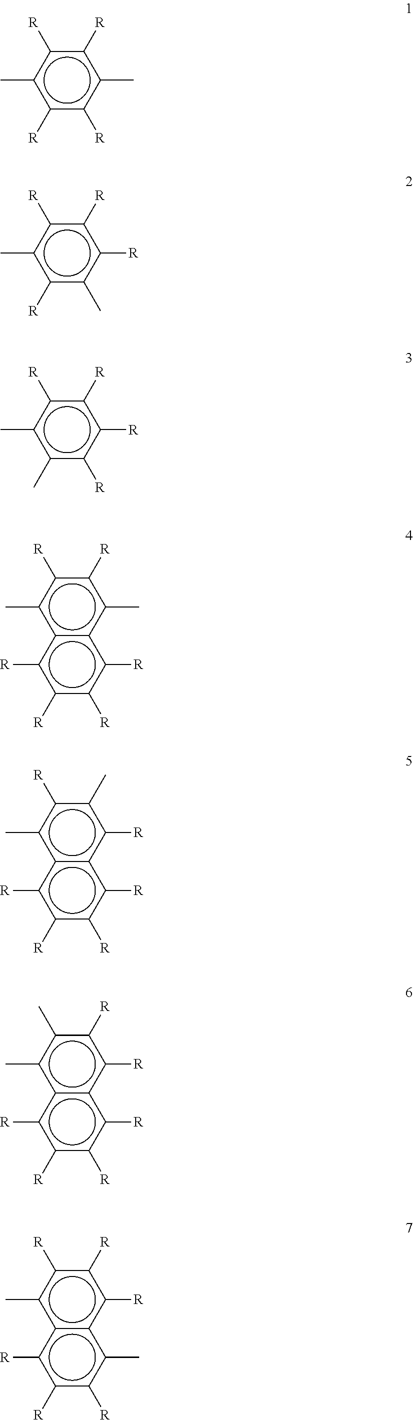

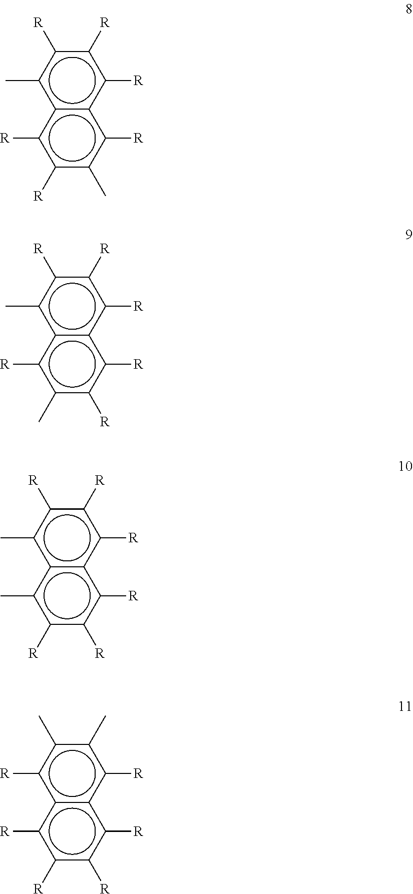

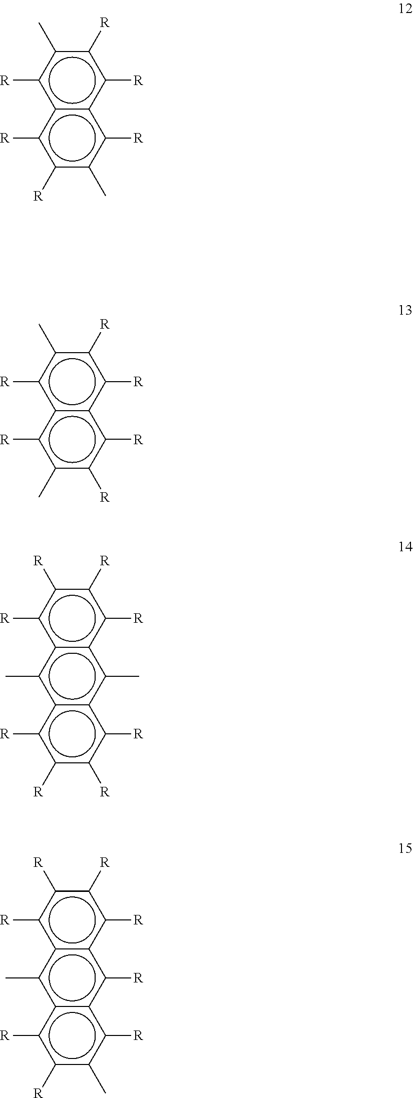

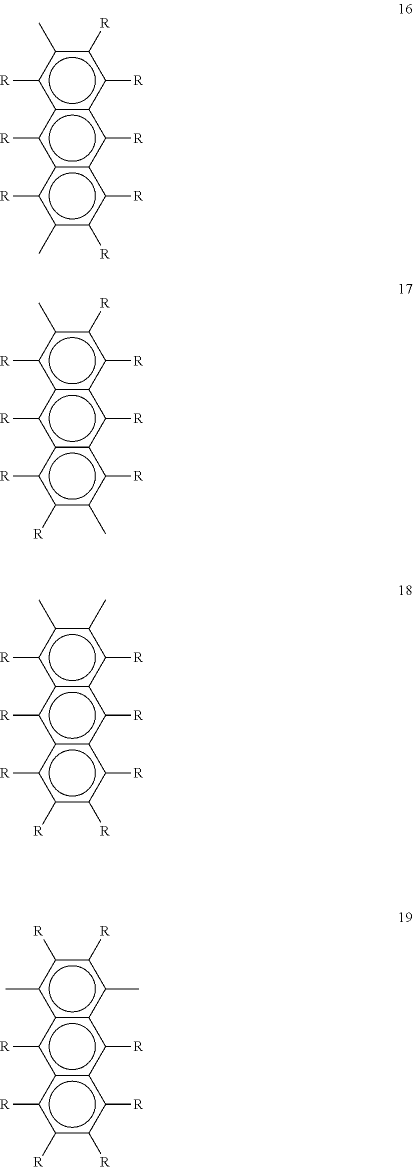

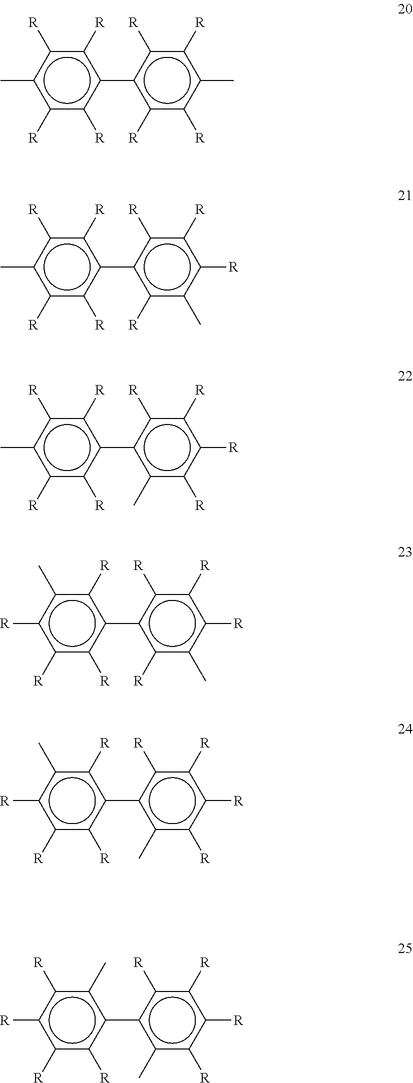

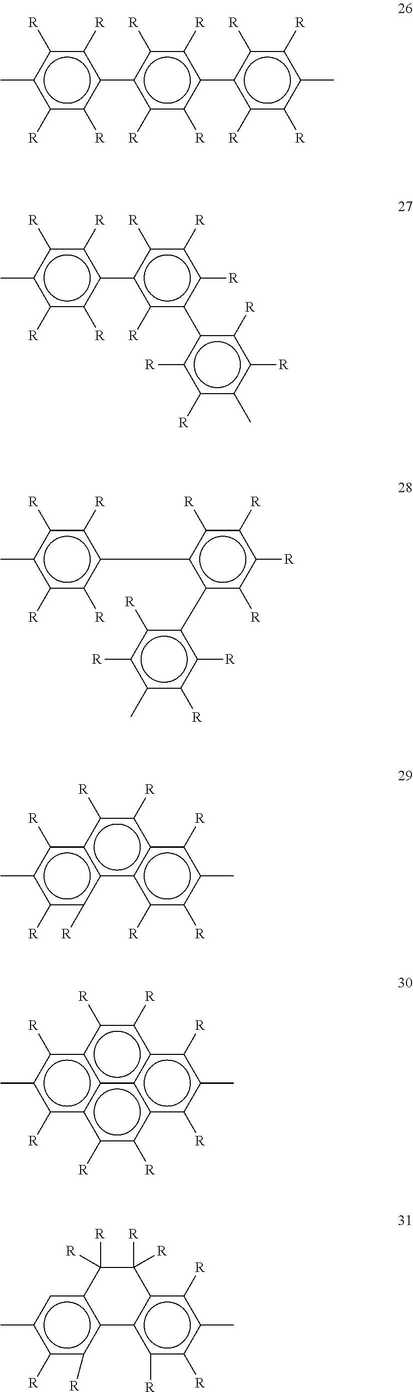

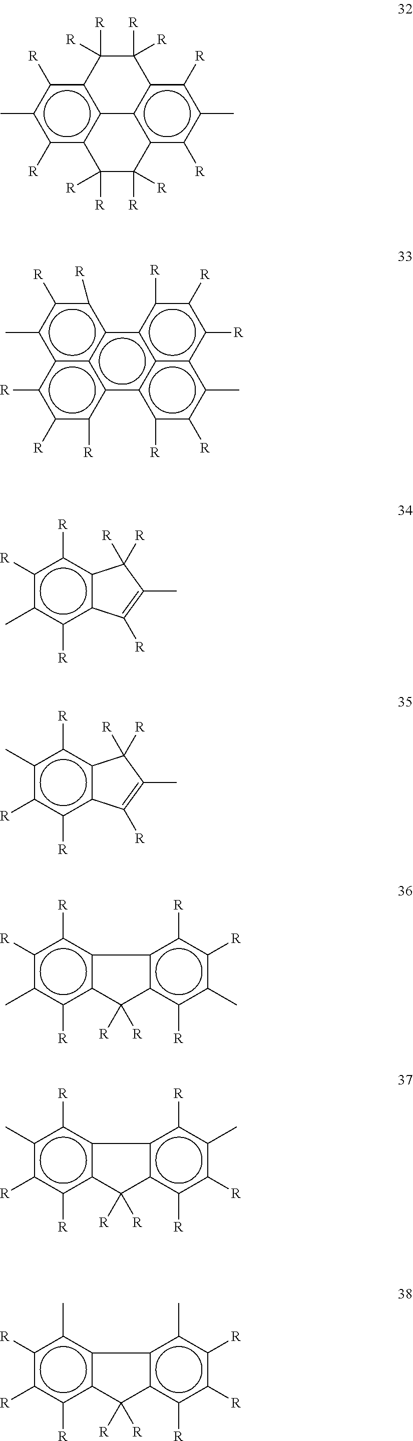

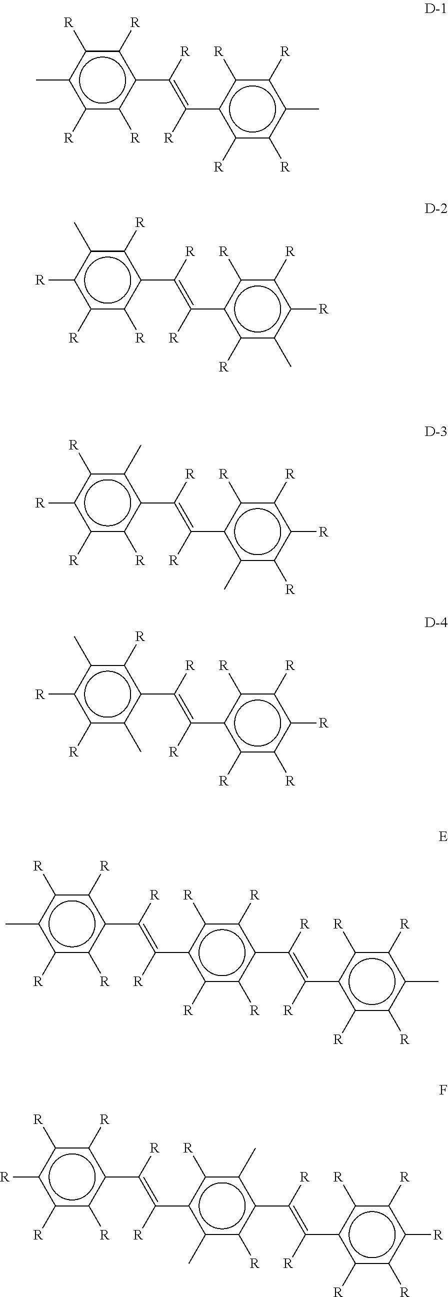

The divalent heterocyclic group in Ar₁, Ar₂, Ar₃, and Ar₄ means an atomic group obtained by removing two hydrogen atoms from a heterocyclic compound, and this heterocyclic group may also have a substituent(s).

The heterocyclic compound means an organic compound having a cyclic structure, in which the ring member elements comprise not only a carbon atom but also a hetero atom such as oxygen, sulfur, nitrogen, phosphorous, boron, arsenic and/or the like. An aromatic heterocyclic group is preferable among the divalent heterocyclic groups.

The substituents described above include an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group.

The divalent heterocyclic group, from which the substituent(s) is excluded, typically has a carbons number of about 3 to 60. In addition, the total carbon number of the divalent heterocyclic group including such substituents is usually about 3 to 100.

The divalent heterocyclic groups include, for example the following:

a divalent heterocyclic group containing nitrogen as a hetero atom, such as a pyridine-diyl group (the following formulas 39 to 44), a diazaphenylene group (the following formulas 45 to 48), a quinolinediyl group (the following formulas 49 to 63), a quinoxalinediyl group (the following formulas 64 to 68), an acridinediyl group (the following formulas 69 to 72), a bipyridyldiyl group (the following formulas 73 to 75), and a phenanthrolinediyl group (the following formulas 76 to 78);

a group having a fluorene structure which contains silicon, nitrogen, selenium and/or the like as a hetero atom (the following formulas 79 to 93);

a five-membered ring heterocyclic group containing silicon, nitrogen, sulfur, selenium and/or the like as a hetero atom (the following formulas 94 to 98);

a five-membered ring condensed heterocyclic group containing silicon, nitrogen, selenium and/or the like as a hetero atom (the following formulas 99 to 108;

a dimmer or oligomer of five-membered ring heterocyclic groups containing silicon, nitrogen, sulfur, selenium and/or the like as a hetero atom, where the heterocyclic groups are bound to each other at an α-position of the hetero atom (the following formulas 109 to 112);

a five-membered ring heterocyclic group containing silicon, nitrogen, sulfur, selenium and/or the like as a hetero atom, and connected to a phenyl group at an α-position of the hetero atom (the following formulas 113 to 119); and

a five-membered ring condensed heterocyclic group containing oxygen, nitrogen, sulfur and/or the like as a hetero atom, and substituted by a phenyl group, a furyl group, or a thienyl group (the following formulas 120 to 125).

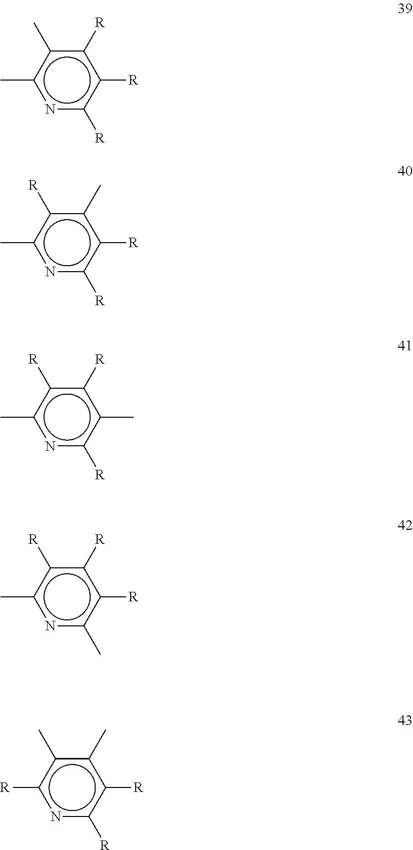

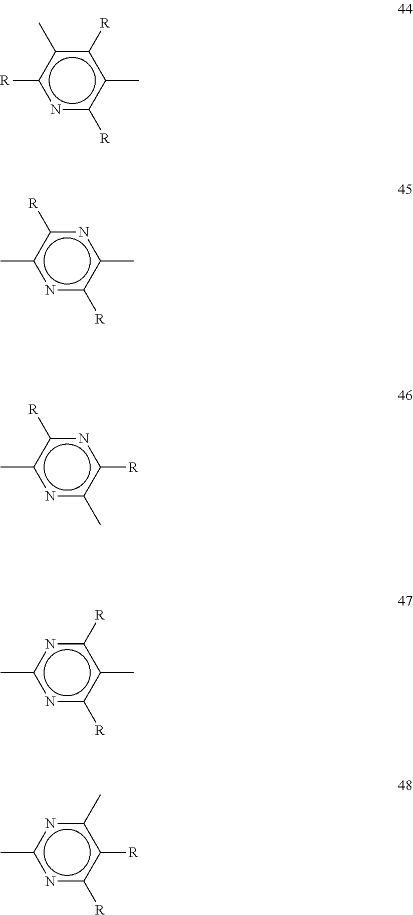

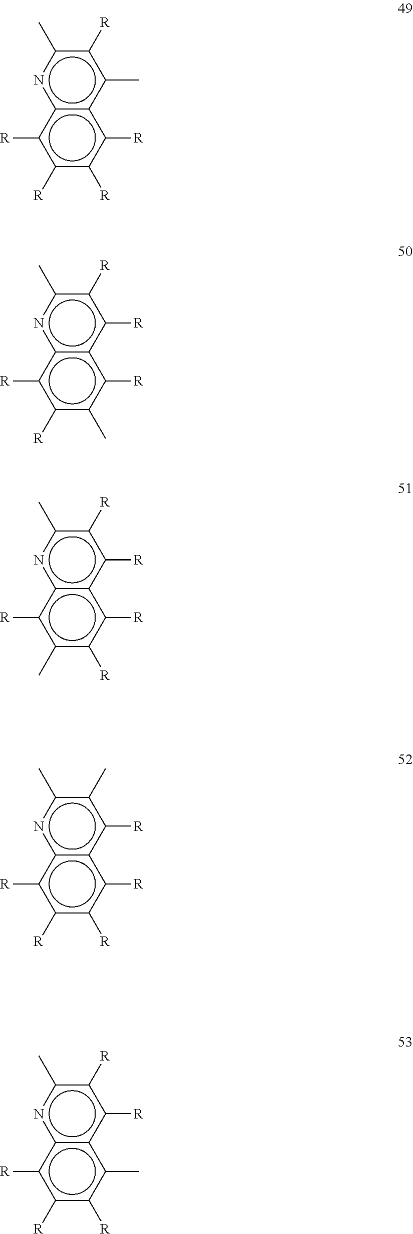

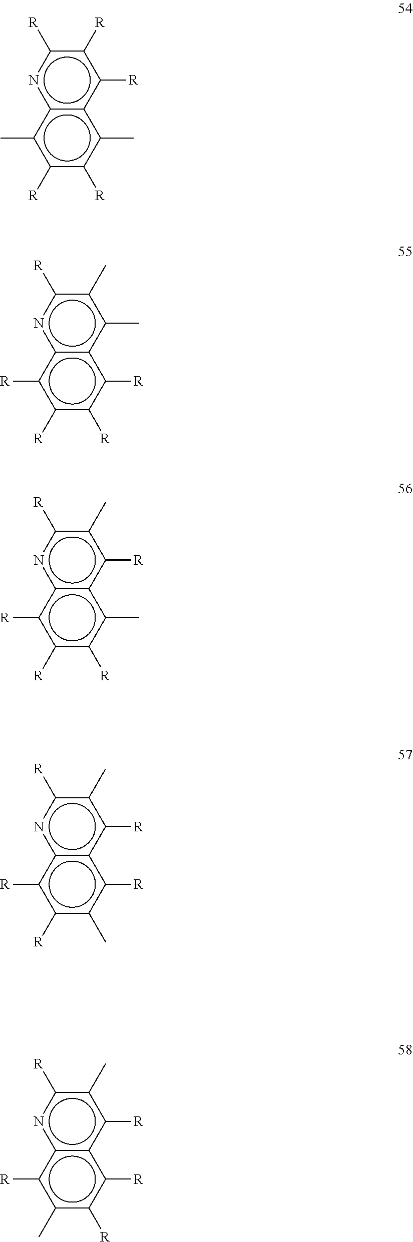

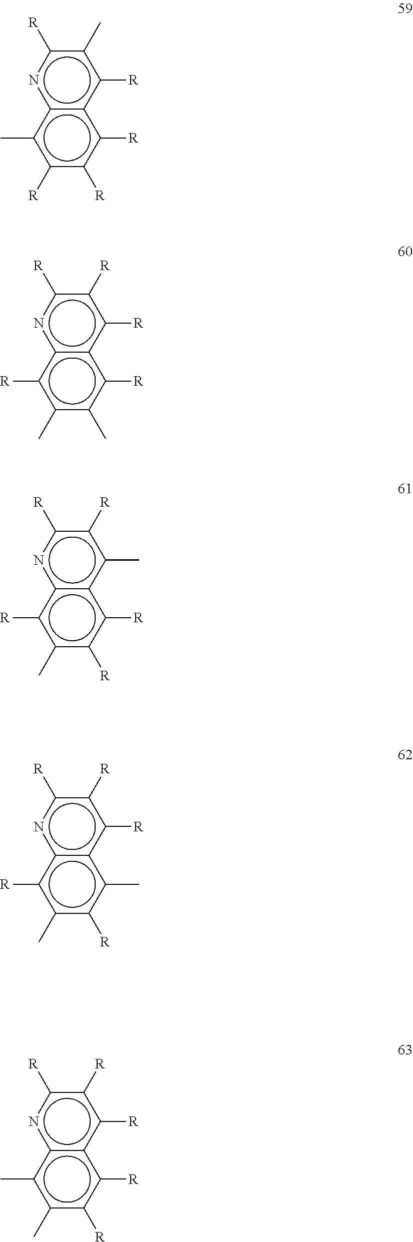

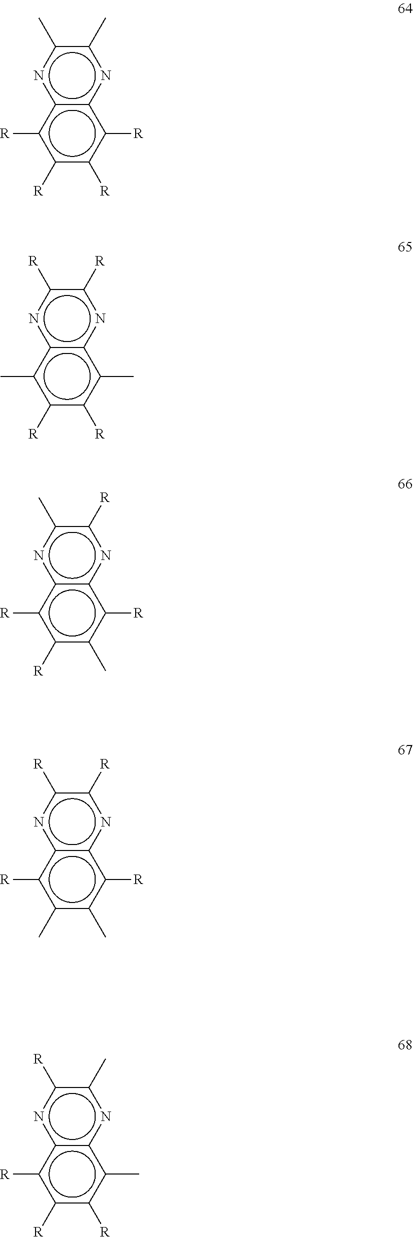

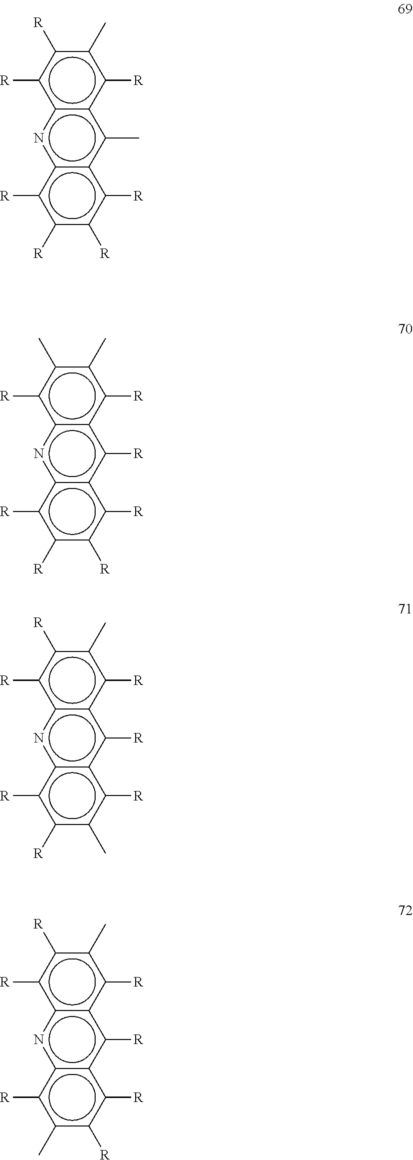

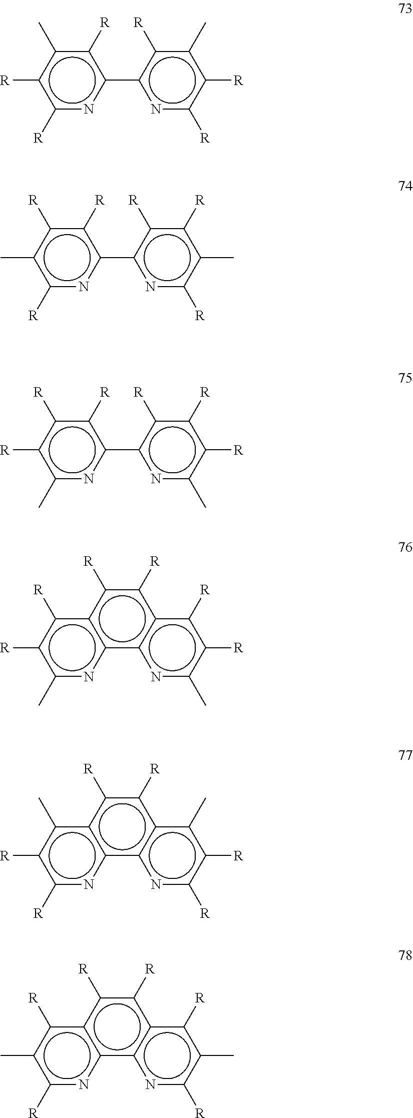

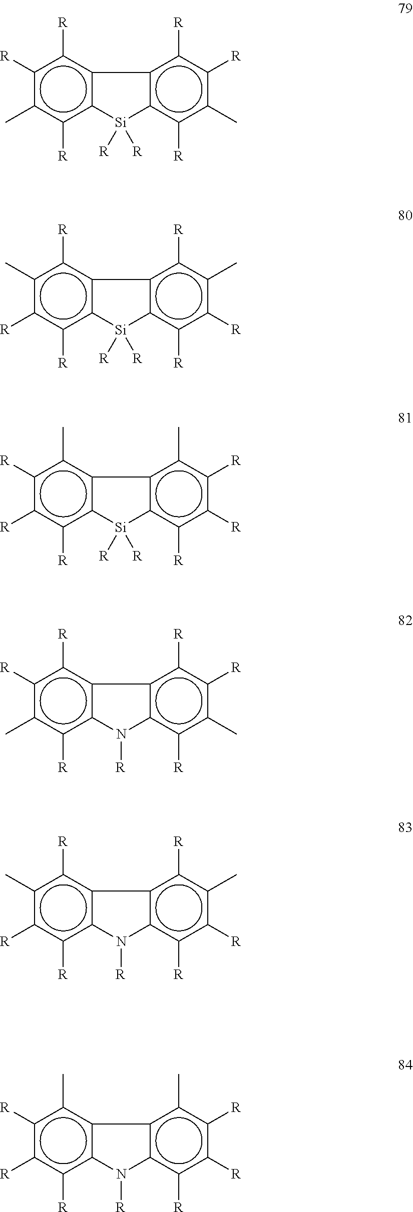

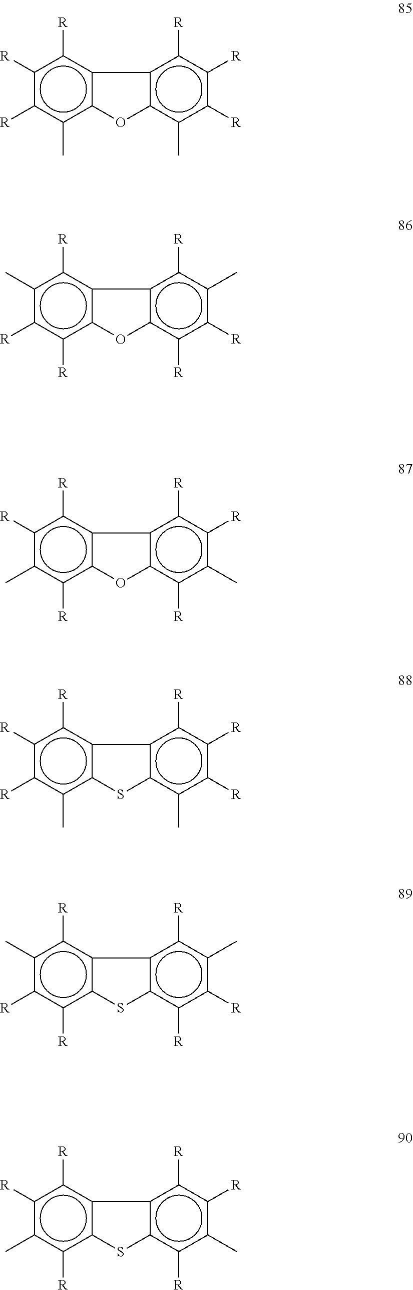

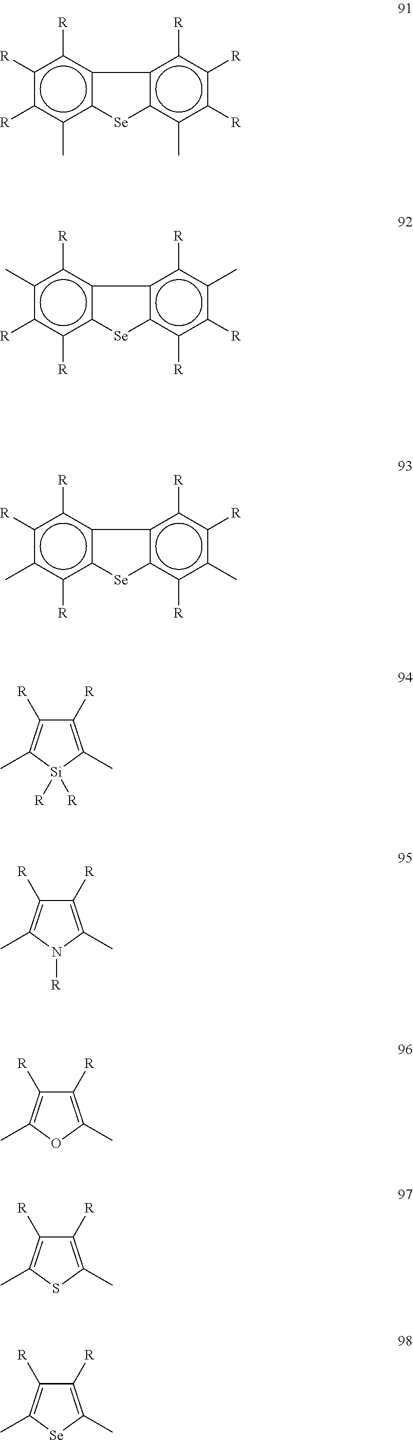

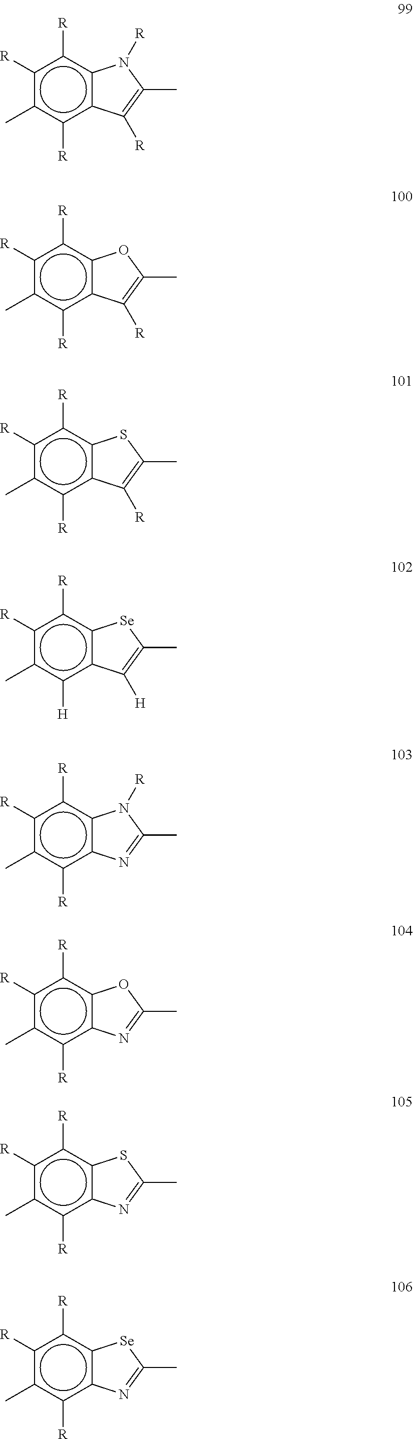

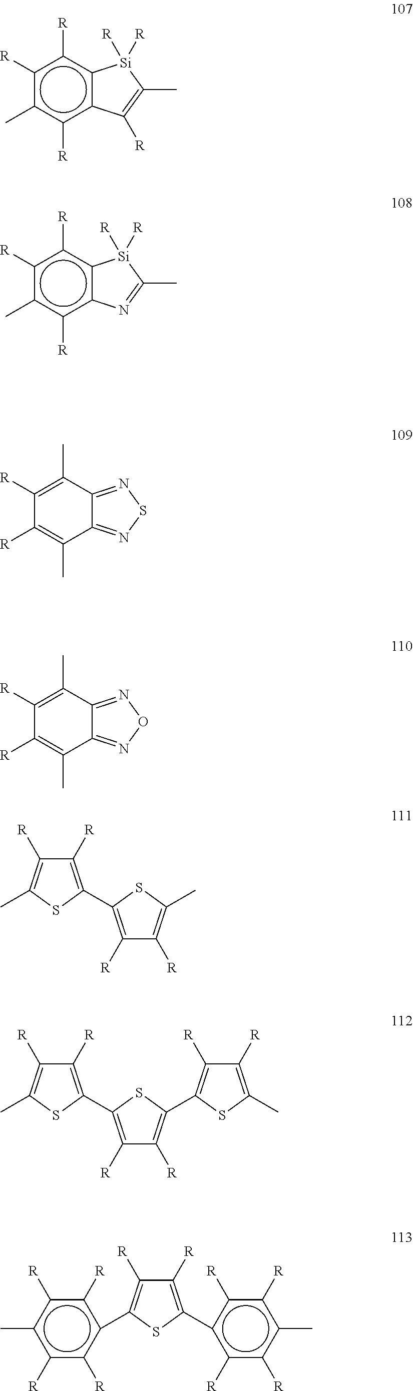

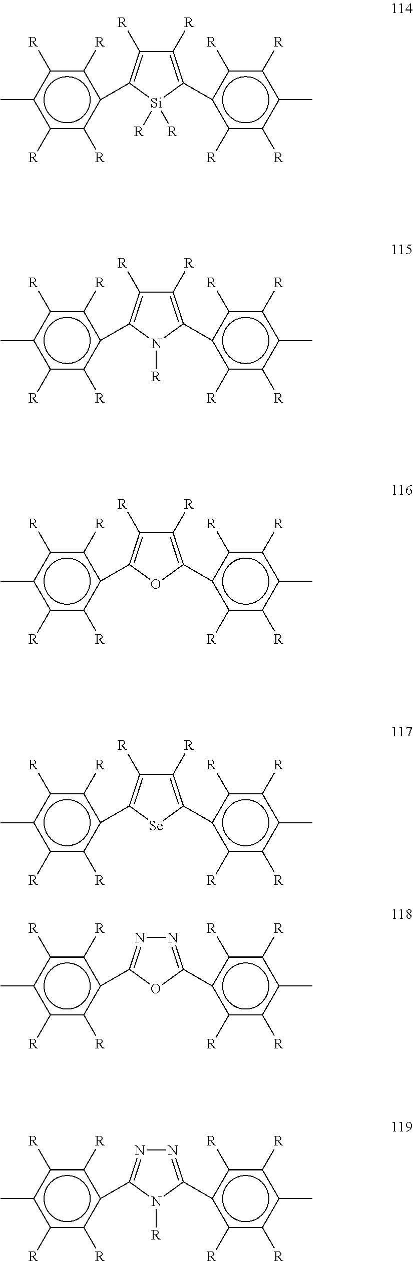

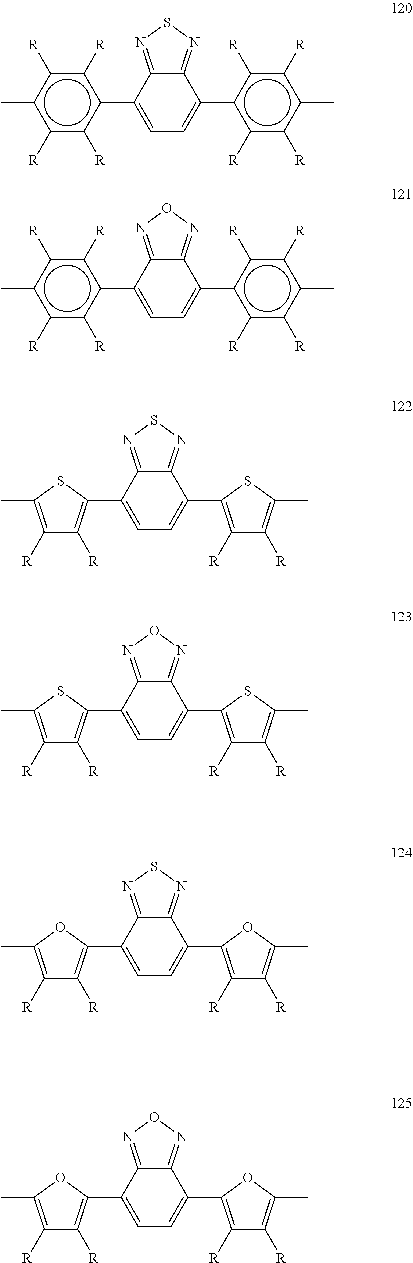

The divalent group having a metal complex structure in Ar₁, Ar₂, Ar₃, and Ar₄ means a divalent group obtained by removing two hydrogen atoms from organic ligands of the metal complex having the organic ligands.

The organic ligand typically has a carbon number of about 4 to 60, and specific examples thereof include 8-quinolinol and derivatives thereof, benzoquinolinol and derivatives thereof, 2-phenyl-pyridine and derivatives thereof, 2-phenyl-benzothiazole and derivatives thereof, 2-phenyl-benzoxazole and derivatives thereof, porphyrin and derivatives thereof.

The central metal of the complex includes aluminum, zinc, beryllium, iridium, platinum, gold, europium, and terbium, for example.

The metal complex having the organic ligands includes metal complexes known as low molecular fluorescent or phosphorescent materials and triplet light-emitting complexes.

Specific examples of the divalent group having a metal complex structure are represented by the following formulas 126 to 132.

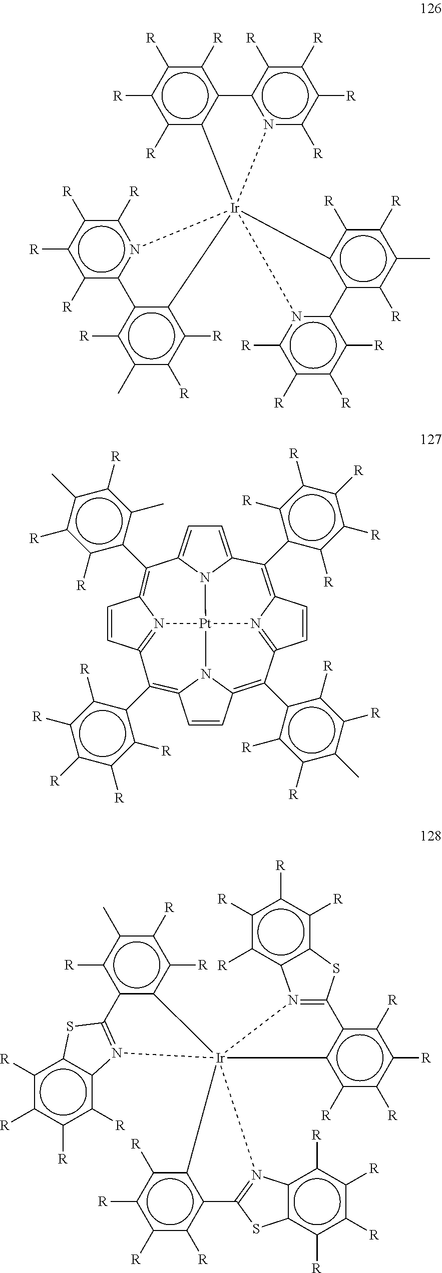

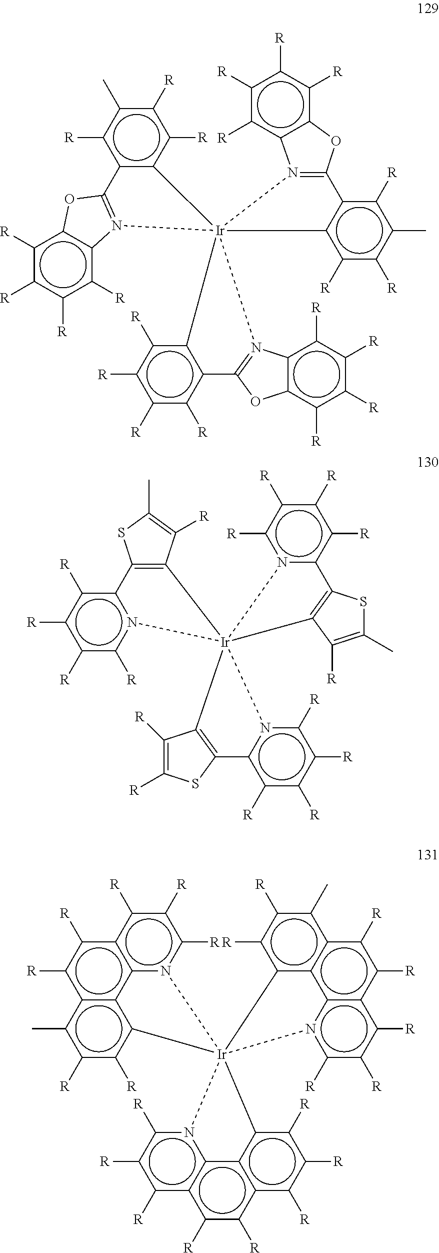

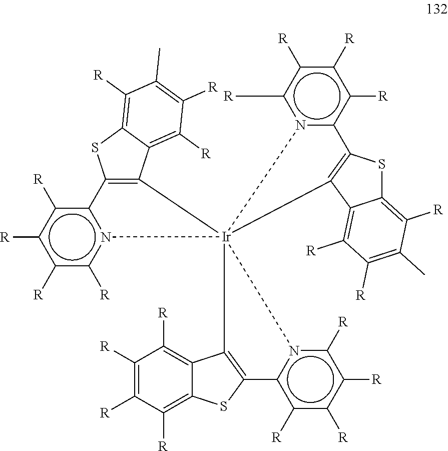

In the above described formulas 1 to 132, R's each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. In the groups represented by the formulas 1 to 132, carbon atoms may be substituted by nitrogen atoms, oxygen atoms, or sulfur atoms, and hydrogen atoms may be substituted by fluorine atoms.

The repeating unit represented by the above described formula (5) is preferably a repeating unit represented by the following formula (10), (11), (12), (13), (14), or (15):

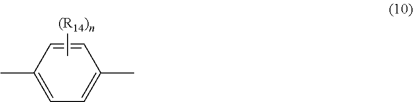

wherein R₁₄ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group, n represents an integer from 0 to 4, and when R₁₄ is present in a plural number, they may be or may not be the same;

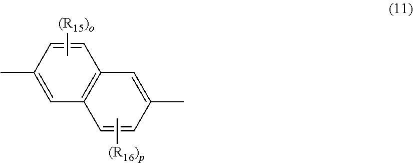

wherein R₁₅ and R₁₆ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group,
o and p each independently represent an integer from 0 to 3, and
when R₁₅ and R₁₆ are respectively present in plural numbers, they may be or may not be the same;

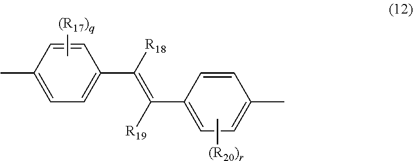

wherein R₁₇ and R₂₀ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group,
q and r each independently represent an integer from 0 to 4,
R₁₈ and R₁₉ each independently represent a hydrogen atom, an alkyl group, an aryl group, a monovalent heterocyclic group, a carboxyl group, a substituted carboxyl group, or a cyano group, and
when R₁₇ and R₂₀ are present in plural numbers, they may be or may not be the same;

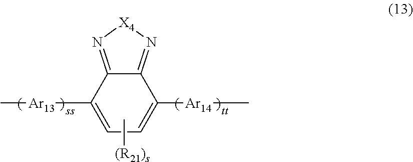

wherein R₂₁ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group, represents an integer from 0 to 2,
Ar₁₃ and Ar₁₄ each independently represent an arylene group, a divalent heterocyclic group, or a divalent group having a metal complex structure,
ss and tt each independently represent 0 or 1,
X₄ represents O, S, SO, SO₂, Se, Te, or —C(R₃₄)═C(R₃₅)—,
R₅ and R₆ respectively represent the same meaning as described above, and
when R₂₁ is present in a plural number, they may be or may not be the same;

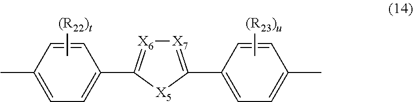

wherein R₂₂ and R₂₅ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group,
t and u each independently represent an integer from 0 to 4,
X₅ represents O, S, SO₂, Se, Te, N—R₂₄, or SiR₂₅R₂₆,
X₆ and X₇ each independently represent N or C—R₂₇,
R₂₄, R₂₅, R₂₆, and R₂₇ each independently represent a hydrogen atom, an alkyl group, an aryl group, an arylalkyl group, or a monovalent heterocyclic group, and
when R₂₂, R₂₃, and R₂₇ are present in plural numbers, they may be or may not be the same (Specific examples of the five-membered ring at the center of the repeating unit represented by the formula (14) include thiadiazole, oxadiazole, triazole, thiophene, furan, silole and the like.); and

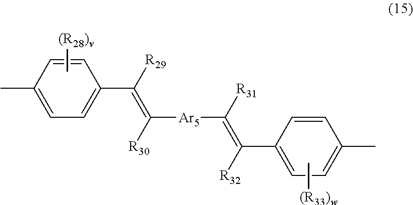

wherein R₂₈ and R₃₃ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group,
v and w each independently represent an integer from 0 to 4,
R₂₉, R₃₀, R₃₁, and R₃₂ each independently represent a hydrogen atom, an alkyl group, an aryl group, a monovalent heterocyclic group, a carboxyl group, a substituted carboxyl group, or a cyano group,
Ar₅ represents an arylene group, a divalent heterocyclic group, or a divalent group having a metal complex structure, and
when R₂₈ and R₃₃ are present in plural numbers, they may be or may not be the same.

The repeating unit represented by the above described formula (6) is preferably a repeating unit represented by the following formula (16) because it is able to change the light-emitting wavelength, to enhance the luminous efficiency, and to improve the heat resistance:

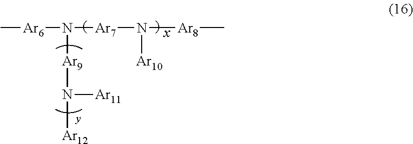

wherein Ar₆, Ar₇, Ar₈, and Ar₉ each independently represent an arylene group or a divalent heterocyclic group;
Ar₁₀, Ar₁₁, and Ar₁₂ each independently represent an aryl group or a monovalent heterocyclic group;
Ar₆, Ar₇, Ar₈, Ar₈, and Ar₁₀ may also have a substituent(s), respectively; and
x and y each independently represent 0 or 1, and satisfy 0≦x+y≦1.

Specific examples of the repeating unit represented by the above described formula (16) include repeating units represented by the following formulas 133 to 142.

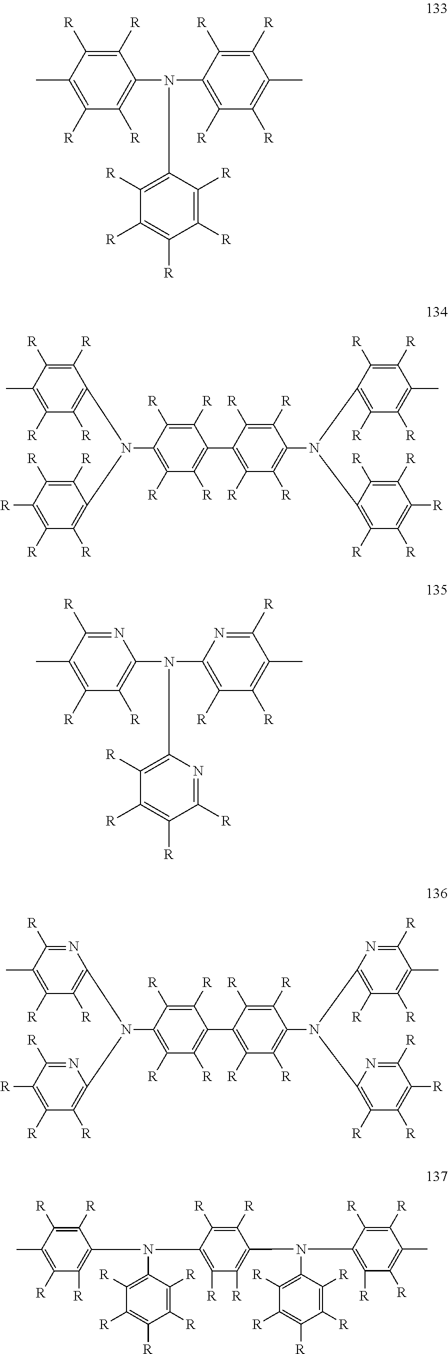

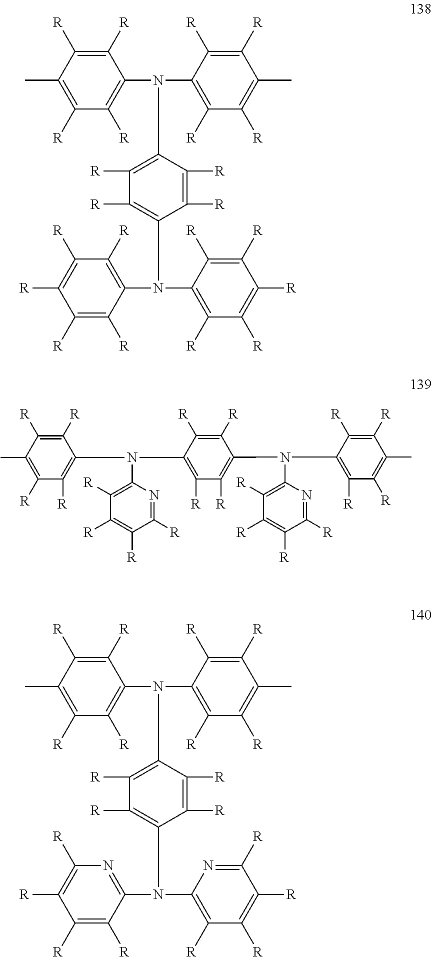

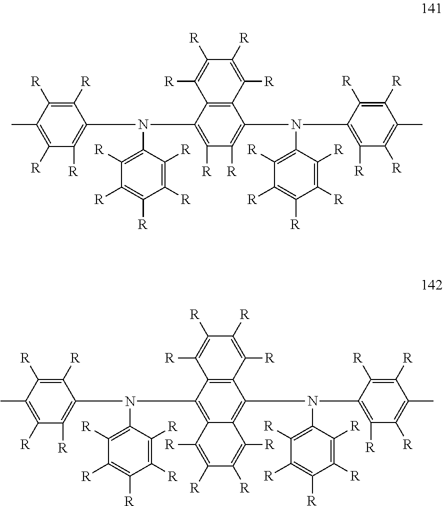

In the above described formulas, R's have the same meanings as described in the above described formulas 1 to 132. In order to make the polymer more soluble in a solvent, it is preferable that one or more atomic groups other than a hydrogen atom be included as R, and that the repeating unit including the substituent(s) has a low symmetric shape.

When the above described formulas have alkyl-containing substituents as R, it is preferable that one or more of the substituents contain cyclic or branched alkyl to make the polymer compound more soluble in a solvent. In addition, if the above described formulas have aryl- or heterocycle-containing groups as R, they may also have one or more substituents.

In the above described formulas 133 to 142, different aromatic rings or heterocyclic rings may be connected via R. Specific examples thereof are represented by the following formulas 143 to 145.

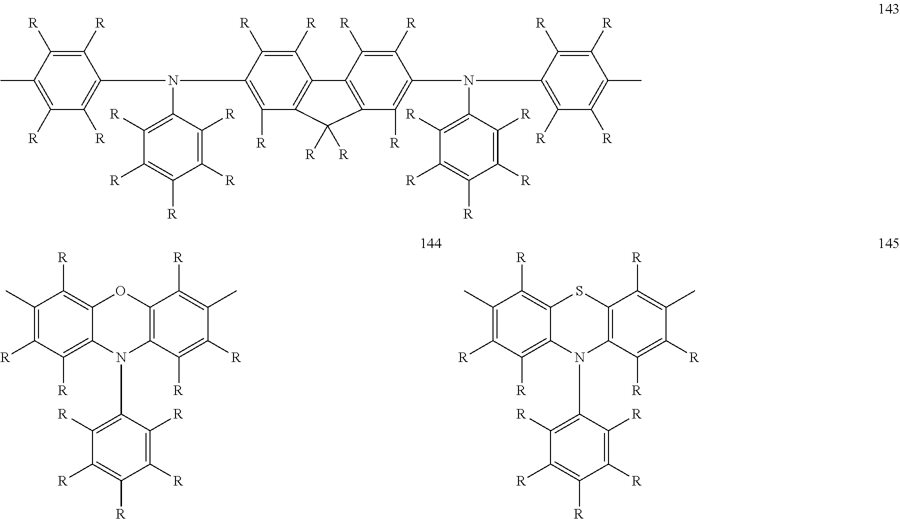

Among the structures represented by the above described formulas 133 to 145, the structures represented by the above described formulas 133, 134, 137, 138, and 141 to 144 are preferable because of their ability to adjust the light-emitting wavelength.

In the repeating units represented by the above described formula (16), it is preferable that Ar₆, Ar₇, Ar₈, and Ar₉ are independently arylene groups and that Ar₁₀, Ar₁₁, and Ar₁₂ each independently represent aryl groups. Among others, it is preferable that Ar₁₀, Ar₁₁, and Ar₁₂ are independently aryl groups having three or more substituents, and it is more preferable that Ar₁₀, Ar₁₁, and Ar₁₂ are phenyl groups having three or more substituents, naphtyl groups having three or more substituents, or anthranil groups having three or more substituents, and it is even more preferable that Ar₁₀, Ar₁₁, and Ar₁₂ are phenyl groups having three or more substituents.

Among others, it is preferable that Ar₁₀, Ar₁₁, and Ar₁₂ are each independently represented by the following formula (16-1) and satisfy x+y=1:

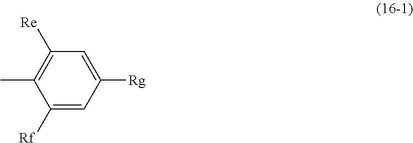

wherein Re, Rf, and Rg each independently represent an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group, or a halogen atom.

In the above described formula (16-1), it is more preferable that Re and Rf are independently alkyl groups having three or less carbons, alkoxy groups having three or less carbons, or alkylthio groups having three or less carbons, while Rg is an alkyl group having 3 to 20 carbons, an alkoxy group having 3 to 20 carbons, or an alkylthio group having 3 to 20 carbons.

The polymer compound according to the present invention is preferably a compound substantially consisting of the repeating unit represented by the above described formula (1), or a compound substantially consisting of the repeating unit represented by the above described formula (1) and one or more repeating units represented by the formulas (5) to (16).

As for the polymer compound according to the present invention, the repeating units may be linked via an unconjugated unit, or the repeating unit may include the unconjugated part. Specific examples of such a linking structure are any of the following structures and a combination of two or more thereof. R described herein is a group selected from the same substituents as described above, and Ar represents a hydrocarbon group having 6 to 60 carbon atoms.

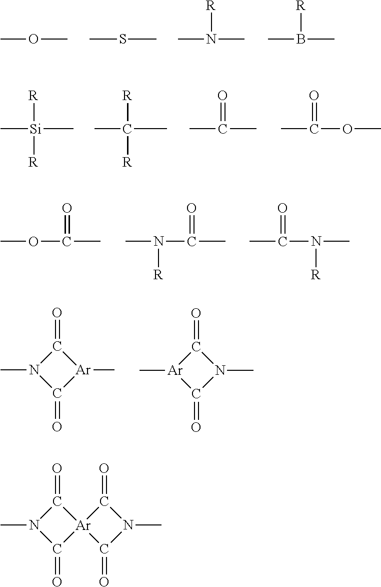

The polymer compound according to the present invention may be an alternating, random, block, or graft copolymer, or alternatively may be a polymer having an intermediate structure therebetween such as a random copolymer having block property. From the viewpoint of obtaining a polymeric fluorescent material which provides a high fluorescent quantum yield, a random copolymer having block property, or a block or graft copolymer is preferable to a completely random copolymer. A polymer having a branched backbone and thus three or more terminals and a dendrimer are also included in the polymer compound of the present invention.

In addition, the terminal groups of the polymer compound according to the present invention may be protected by a stable group, because a polymerizable group remaining at the terminal groups may lower the light emission characteristic and lifetime of a device to be fabricated from the polymer compound. A preferable stable group is a group having a conjugated bond so that it is continuously connected to the conjugated structure of the polymer backbone, for example, a structure which is bonded to an aryl group or a heterocyclic group via a carbon-carbon bonding. A specific example thereof is a substituent or the like represented by Formula 10 of JP-A-09-45478.

The polymer compound of the present invention has a polystyrene reduced weight-average molecular weight, usually of about 10³ to 10⁸, and preferably 10⁴ to 10⁶.

Examples of good solvents for the polymer compound include chloroform, methylene chloride, dichloroethane, tetrahydrofuran, toluene, xylene, mesitylene, tetralin, decalin, n-butylbenzene, and the like. The polymer compound can usually be dissolved at a level of 0.1 wt % or more in these solvents, depending on the structure or molecular weight of the polymer compound.

Next, a method for producing a polymer compound of the present invention will be described. The polymer compound of the present invention can be produced by polymerizing a compound (A) represented by the following formula:

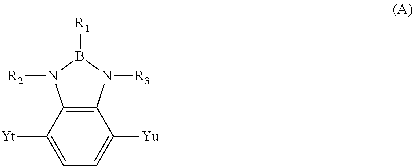

wherein Yₜ and Yᵤ each independently represent substituents which are involved in polymerization; and R₁, R₂, and R₃ represent the same meaning as described above.

A mode of polymerization is preferably condensation polymerization.

If the polymer compound of the present invention is a copolymer including repeating units other than the above described formula (1), the copolymer can be produced by polymerization which uses as a raw material, in addition to (A), a compound constituted of repeating units other than the above described formula (1) (a repeating unit represented by the above described formula (5), (6), (7), or (8), for example) whose dangling bond is attached to a substituent involved in the polymerization for example.

The substituents involved in the polymerization include halogen atom, alkyl sulfonate group, aryl sulfonate group, arylalkyl sulfonate group, borate group, sulfonium methyl group, phosphonium methyl group, phosphonate methyl group, monohalogenated methyl group, —B(OH)₂, formyl group, cyano group, and vinyl group.

Although a preferable substituent involved in the polymerization varies depending on the type of polymerization reaction, examples of such substituents include a halogen atom, an alkyl sulfonate group, an aryl sulfonate group, and an arylalkyl sulfonate group if a zero-valence nickel complex is used as in the Yamamoto coupling reaction. If a nickel catalyst or a palladium catalyst is used as in the Suzuki coupling reaction, examples of such substituents are an alkyl sulfonate group, a halogen atom, a borate ester group, —B(OH)₂ and the like.

For the halogen atom used in this case a bromine atom or a iodine atom is preferable.

Illustrative examples of a borate ester group include groups and the like represented by the following formulas:

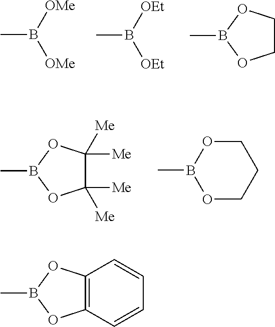

wherein Me represents a methyl group; and
Et represents an ethyl group.

In addition, the polymer compound of the present invention can also be produced by reaction of a polymer compound containing a structure represented by formula (2) described below with the compound represented by the formula (C) described below.

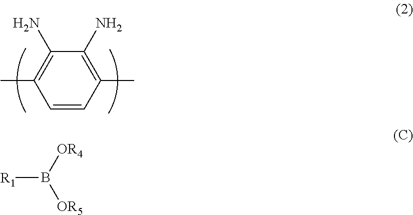

wherein R₁ represents the same meaning as described above; and
R₄ and R₅ each independently represent a hydrogen atom or a substituent, or R₄ and R₅ together form a ring. Illustrative examples of the substituents in this case include an alkyl group such as a methyl group and an ethyl group.

The total amount of the repeating unit represented by the above described formula (2) is usually 1 mol % or more and 100 mol % or less, and is preferably 10 mol % or more and 90 mol % or less with respect to all repeating units included in the polymer compound having a structure represented by the above described formula (2).

If the polymer compound having a structure represented by the above described formula (2) includes repeating units other than the above described formula (1), an example thereof is a repeating unit represented by the above described formula (5), (6), (7), or (8).

When the polymer compound including a structure represented by the above described formula (2) is reacted with a compound represented by the above described formula (C), it is preferable that a ratio of the number of moles (K) of the repeating unit represented by the above described formula (2) to the number of moles (J) of the compound represented by the above described formula (C) is substantially 1 (usually, K/J is in a range of 0.5 to 1.3).

The reaction of the polymer compound including a structure represented by the above formula (2) with the compound represented by the above described formula (C) can be specifically performed by dissolving the polymer compound and the compound in an organic solvent as needed at a temperature from a melting point to a boiling point of the organic solvent.

The reaction is usually carried out in an atmosphere of an inactive gas such as argon, nitrogen or the like. A reaction time is usually about 0.5 to 120 hours, and is preferably within 100 hours and more preferably within 80 hours in terms the production cost.

A reaction temperature is usually about 0 to 200° C., and is preferably 20 to 150° C. in terms of a high yield and a low heating cost.

After completing the reaction, the product may also be subjected to a common separation or purification operation such as acid washing, alkali washing, neutralization, water washing, organic solvent washing, reprecipitation, centrifugation, extraction or column chromatography and drying and other operations as needed.

In the above described formula (C), the substituent represented by R₁ is preferably selected from an alkyl group and an aryl group, and an aryl group is more preferred.

Illustrative examples of the compound of the above described formula (C) include R₁—B(OH)₂ and a compound having R₁ and a borate ester group which are bonded together.

In this case, the polymer compound containing the structure represented by the above described formula (2) can be produced by polymerization of a compound represented by the following formula (B):

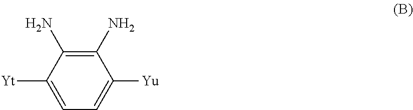

wherein Yₜ and Yᵤ represent the same meaning as described above.

When the polymer compound of the present invention is produced by condensation polymerization, the Heck reaction between a compound having a vinyl group and a compound having a halogen atom can be utilized in order to produce a double bond in a backbone. Alternatively, a Heck reaction, the Sonogashira reaction or the like can be employed in order to produce a triple bond in a backbone, when the polymer compound of the present invention is produced by the condensation polymerization.

If the double bond or the triple bond is not intended to be produced, it is possible to use other methods such as by polymerizing monomers of interest through the Suzuki coupling reaction, polymerizing monomers of interest through the Grignard reaction, polymerizing monomers of interest by a Ni (0) complex, polymerizing monomers of interest by an oxidizing agent such as FeCl₃, electrochemically performing oxidative polymerization of monomers of interest, or by decomposing an intermediate polymer having an appropriate leaving group.

The compound represented by the above described formula (A) can be produced by reaction of the compound represented by the above described formula (B) with the compound represented by the above described formula (C). In the above described formula (C), the substituent represented by R₁ is preferably selected from an alkyl group and an aryl group.

Now, the polymer LED of the present invention will be described.

The polymer LED of the present invention is characterized by having an organic layer between a positive electrode and a negative electrode, said organic layer comprising the polymer compound of the present invention or the composition of the present invention.

Although the layer comprising the polymer compound (organic layer) may be any of a light emitting layer, a hole transport layer, an electron transport layer and the like, the light emitting layer is preferable.

The light emitting layer used herein means a layer which has a light emitting function, the hole transport layer means a layer which has a hole transporting function, and the electron transport layer means a layer which has an electron transporting function. The electron transport layer and the hole transport layer are collectively referred to as a charge transport layer. It may be also possible for the light emitting layer, the hole transport layer, and the electron transport layer to each independently comprise two or more layers.

If a layer comprising the polymer compound is the light emitting layer, this light emitting layer may further include a hole transport material, an electron transport material, or a light emitting material. The light emitting material used herein means a material which produces fluorescence and/or phosphorescence.

If the polymer compound of the present invention is mixed with the hole transport material, the hole transport material to be mixed has a mixing proportion of 1 wt % to 80 wt % and preferably 5 wt % to 60 wt % with respect to the whole organic material. If the electron transport material is mixed with the polymer compound used for the present invention, the electron transport material to be mixed has an mixing proportion of 1 wt % to 80 wt % and preferably 5 wt % to 60 wt % with respect to the whole organic material. Further, if the light emitting material is mixed with the polymer compound used for the present invention, the light emitting material to be mixed has a mixing proportion of 1 wt % to 80 wt % and preferably 5 wt % to 60 wt % with respect to a whole organic material. If the light emitting material, the hole transport material, and/or the electron transport material are mixed with the polymer compound used for the present invention, the light emitting material has a mixing proportion of 1 wt % to 50 wt % with respect to the whole organic material and preferably 5 wt % to 40 wt %, and the sum of the hole transport material and the electron transport material has a mixing proportion of 1 wt % to 50 wt % and preferably 5 wt % to 40 wt %, and the polymer compound of the present invention has a content of 99 wt % to 20 wt %.

Although a known low molecular compound or polymer compound can be used as the hole transport material, the electron transport material, or the light emitting material which will be mixed with the inventive polymer, a polymer compound is preferably used. Illustrative examples of the hole transport material, the electron transport material, and the light emitting material which are all polymeric are polyfluorene and derivatives and copolymers thereof, polyarylene and derivatives and copolymers thereof, polyarylenevinylene and derivatives and copolymers thereof, and aromatic amine and derivatives and copolymers thereof as disclosed in WO99/13692, WO99/48160, GB2340304A, WO00/53656, WO01/19834, WO00/55927, GB2348316, WO00/46321, WO00/06665, WO99/54943, WO99/54385, U.S. Pat. No. 5,777,070, WO98/06773, WO97/05184, WO00/35987, WO00/53655, WO01/34722, WO99/24526, WO00/22027, WO00/22026, WO98/27136, U.S. Pat. No. 573,636, WO98/21262, U.S. Pat. No. 5,741,921, WO97/09394, WO96/29356, WO96/10617, EP0707020, WO95/07955, JP-A-2001-181618, JP-A-2001-123156, JP-A-2001-3045, JP-A-2000-351967, JP-A-2000-303066, JP-A-2000-299189, JP-A-2000-252065, JP-A-2000-136379, JP-A-2000-104057, JP-A-2000-80167, JP-A-10-324870, JP-A-10-114891, JP-A-09-111233, JP-A-09-45478 and the like.

As the fluorescent material produced by the low molecular compound, naphthalene derivatives, anthracene or derivatives thereof, perylene or derivatives thereof, polymethine, xanthene, coumarin, cyanine and other dyes, 8-hydroquinoline or metal complex derivatives thereof, aromatic amine, tetraphenylcyclopentadiene or derivatives thereof, tetraphenylbutadiene or derivatives thereof or the like can be used.

Specifically, well-known materials described in JP-A-57-51781, JP-A-59-194393 and the like can be used.

Among phosphorescent materials produced by the low molecular compound are triplet light-emitting complexes such as Ir(ppy)₃ or Btp₂Ir(acac) (a central metal thereof is iridium), PtOEP (a cenral metal thereof is platinum), and Eu(TTA)₃phen (a central metal thereof is europium).

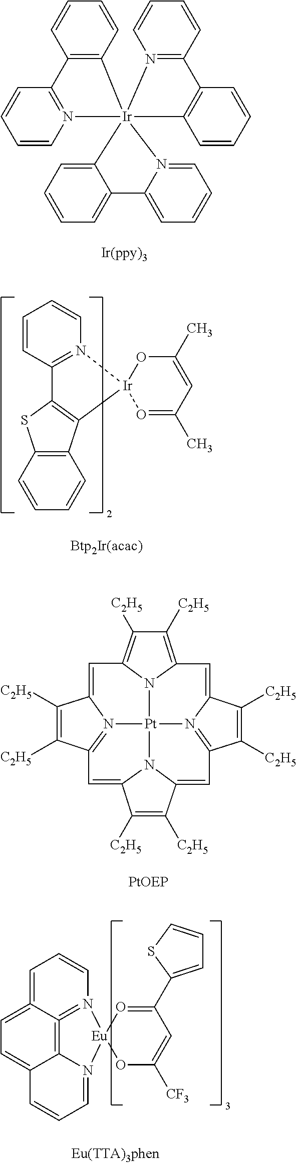

Specific examples of the triplet light-emitting complexes are described in Nature, (1998), 395, 151, Appl. Phys. Lett. (1999), 75(1), 4, Proc. SPIE-Int. Soc. Opt. Eng. (2001), 4105 (Organic Light-Emitting Materials and Devices IV), 119, J. Am. Chem. Soc., (2001), 123, 4304, Appl. Phys. Lett., (1997), 71(18), 2596, Synth. Met., (1998), 94(1), 103, Synth. Met., (1999), 99(2), 1361, Adv. Mater., (1999), 11(10), 852, Jpn. J. Appl. Phys., 34, 1883 (1995), for example.

An optimal value of a thickness of the light-emitting layer which is contained in the polymer LED of the present invention varies depending on the material to be used, and may be selected such that a driving voltage and a luminous efficiency become moderate values, however, the optimal value is 1 nm to 1 μm for example, and is preferably 2 nm to 500 nm, and is more preferably 5 nm to 200 nm.

An illustrative example of a method for forming the light-emitting layer relies on the deposition from a solution. As a method for depositing a layer from a solution, it is possible to use a coating method such as a spin coat method, a casting method, a micro gravure coating method, a gravure coating method, a bar coat method, a roll coat method, a wire bar coat method, a dip coat method, a spray coat method, a screen printing method, a flexographic printing method, an offset printing method, an inkjet printing method or the like.

An ink composition used for such printing methods must contain at least one polymer compound of the present invention, and may also include additives such as a hole transport material, an electron transport material, a light-emitting material, a solvent, and a stabilizing agent, other than the polymer compound of the present invention.

The polymer compound according to the present invention contained in the ink composition accounts for 20 wt % to 100 wt %, and preferably 40 wt % to 100 wt % of the total weight of the composition other than the solvent.

When the ink composition contains a solvent, the solvent accounts for 1 wt % to 99.9 wt %, preferably 60 wt % to 99.5 wt %, and more preferably 80 wt % to 99.0 wt % of the total weight of the composition.

Although the viscosity of the ink composition varies depending on the printing method, the viscosity at 25° C. is preferably within a range of 1 to 20 mPa·s in order to prevent plugging or flying in a wrong direction at the time of ejection, if the ink composition goes through an ejection apparatus as in inkjet printing or the like.

Although the solvent used for the ink composition is not specifically limited, it is preferable to use a solvent which can dissolve or uniformly disperse materials constituting the ink composition other than the solvent. If the materials constituting the ink composition are soluble in a nonpolar solvent, illustrative examples of the solvents include a chlorine-containing solvent such as chloroform, methylene chloride, or dichloroethane, an ether solvent such as tetrahydrofuran, an aromatic hydrocarbon solvent such as toluene or xylene, a ketone solvent such as acetone or methylethylketone, and an ester solvent such as ethyl acetate, butyl acetate, ethylcellosolve acetate. Each of these solvents can be used alone or in combination with each other.

Among the polymer LEDs of the present invention are a polymer LED in which an electron transport layer is provided between a negative electrode and a light-emitting layer, a polymer LED in which a hole transport layer is provided between a positive electrode and a light-emitting layer, and a polymer LED in which an electron transport layer is provided between a negative electrode and a light-emitting layer and further a hole transport layer is provided between a positive electrode and a light-emitting layer.

For example, specific examples of such structures are as follows:

a) positive electrode/light-emitting layer/negative electrode;
b) positive electrode/hole transport layer/light-emitting layer/negative electrode;
c) positive electrode/light-emitting layer/electron transport layer/negative electrode; and
d) positive electrode/hole transport layer/light-emitting layer/electron transport layer/negative electrode.
(/ herein represents that respective layers are laminated in contact with each other. The same will apply hereinafter.)

If the polymer LED according to the present invention has a hole transport layer, illustrative examples of the hole transport materials to be used are polyvinyl carbazole or derivatives thereof, polysilane or derivatives thereof, polysiloxane derivatives having aromatic amines on side chains or backbone thereof, pyrazoline derivatives, arylamine derivatives, stilbene derivatives, triphenyldiamine derivatives, polyaniline or derivatives thereof, polythiophene or derivatives thereof, polypyrrole or derivatives thereof, poly(p-phenylenevinylene) or derivatives thereof, or poly(2,5-thienylenevinylene) or derivatives thereof.

Specific examples of the hole transport materials are described in JP-A-63-70257, JP-A-63-175860, JP-A-02-135359, JP-A-02-135361, JP-A-02-209988, JP-A-03-37992, and JP-A-03-152184.

Among these hole transport materials used for the hole transport layer are preferably polymeric hole transport materials such as polyvinylcarbazole or derivatives thereof, polysilane or derivatives thereof, polysiloxane derivatives having aromatic amine compound groups on side chains or backbone thereof, polyaniline or derivatives thereof, polythiophene or derivatives thereof, poly(p-phenylenevinylene) or derivatives thereof, or poly(2,5-thienylenevinylene) or derivatives thereof, and more preferably polyvinylcarbazole or derivatives thereof, polysilane or derivatives thereof, and polysiloxane derivatives having aromatic amines on side chains or backbone thereof.

Illustrative examples of hole transport materials made from low molecular compounds are pyrazoline derivatives, arylamine derivatives, stilbene derivatives, and triphenyldiamine derivatives. In the case of low molecular hole transport materials, such materials are preferably used by being dispersed in a polymer binder.

As the polymer binder to be mixed, a material which does not extremely inhibit the charge transport is preferable, and a material which does not strongly absorb a visible light is favorably used. Illustrative examples of the polymer binder are poly(N-vinylcarbazole), polyaniline or derivatives thereof, polythiophene or derivatives thereof, poly(p-phenylenevinylene) or derivatives thereof, poly(2,5-thienylenevinylene) or derivatives thereof, polycarbonate, polyacrylate, polymethyl acrylate, polymethyl methacrylate, polystyrene, polyvinyl chloride, polysiloxane and the like.

Polyvinylcarbazole or derivatives thereof can be obtained by cationic polymerization or radical polymerization of vinyl monomers, for example.

Illustrative examples of polysilane or derivatives thereof are compounds which are described in Chem. Rev., 89, 1359 (1989) and GB 2300196 A. Method for synthesizing which are also described in these publications can be used, and specifically the Kipping method is favorably used.

A siloxane skeletal structure of polysiloxane or a derivative thereof has little hole transporting property, so that a material which has on side chains or backbone thereof a structure of the above described low molecular hole transport material is favorably used. Specific examples thereof are materials which have, on side chains or backbone thereof, aromatic amines provided with hole transporting properties.

The method of depositing the hole transport layer is not limited, but for a low molecular weight hole transport material, a method for depositing it from a mixed solution with a polymer binder is exemplary illustrated. As for the polymeric hole transport materials, an illustrative example thereof is a method relying on deposition from a solution.

A solvent used for the deposition from the solution is not specifically limited, as long as the solvent can dissolve the hole transport material. Illustrative examples of such solvents are a chlorine-containing solvent such as chloroform, methylene chloride, or dichloroethane, an ether solvent such as tetrahydrofuran, an aromatic hydrocarbon solvent such as toluene or xylene, a ketone solvent such as acetone or methylethylketone, and an ester solvent such as ethyl acetate, butyl acetate, ethylcellosolve acetate.

As a method for depositing a layer from a solution, it is possible to use a method of coating from a solution such as a spin coat method, a casting method, a micro gravure coating method, a gravure coating method, a bar coat method, a roll coat method, a wire bar coat method, a dip coat method, a spray coat method, a screen printing method, a flexographic printing method, an offset printing method, an inkjet printing method or the like.

An optimal value of a film thickness of the hole transport layer varies depending on the material to be used, and may be selected such that a driving voltage and a luminous efficiency become moderate values, however, this layer should have at least a thickness which never allows a pinhole to be created, whereas it is not preferable to have a too much thickness because a driving voltage of a device becomes higher. Therefore, a film thickness of the hole transport layer is 1 nm to 1 μm for example, and preferably 2 nm to 500 nm, and more preferably 5 nm to 200 nm.

When the polymer LED according to the present invention has an electron transport layer, well-known materials can be used as electron transport material for such layer, and illustrative examples thereof are oxadiazole derivatives, anthraquinodimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinone derivatives, or metal complexes of 8-hydroxyquinoline or derivatives thereof, polyquinoline or derivatives thereof, polyquinoxaline or derivatives thereof, polyfluorene or derivatives thereof.

Specifically, illustrative examples thereof are described in JP-A-63-70257, JP-A-63-175860, JP-A-02-135359, JP-A-02-135361, JP-A-02-209988, JP-A-03-37992, and JP-A-03-152184.

Among the above described materials are preferably oxadiazole derivatives, benzoquinone or derivatives thereof, anthraquinone or derivatives thereof, or metal complexes of 8-hydroxyquinoline or derivatives thereof, polyquinoline or derivatives thereof, polyquinoxaline or derivatives thereof, polyfluorene or derivatives thereof, and more preferably 2-(4-biphenyl)-5-(4-t-butylphenyl)-1,3,4-oxadiazole, benzoquinone, anthraquinone, tris(8-quinolinole)aluminum, and polyquinoline.

Although the method of depositing the electron transport layer is not specifically limited, an illustrative example of depositing a low molecular electron transport material is a method of vacuum depositing from powders or a method of depositing from a solution or molten state, and an illustrative example of depositing a polymeric electron transport material is a method of depositing from a solution or molten state. At a time of depositing from a solution or molten state, the above described polymer binder may also be used simultaneously.

A solvent used for the deposition from the solution is not specifically limited, as long as the solvent dissolves the electron transport material and/or the polymer binder. Illustrative examples of the solvents are a chlorine-containing solvent such as chloroform, methylene chloride, or dichloroethane, an ether-based solvent such as tetrahydrofuran, an aromatic hydrocarbon-based solvent such as toluene or xylene, a ketone-based solvent such as acetone or methylethylketone, and an ester-based solvent such as ethyl acetate, butyl acetate, ethylcellosolve acetate or the like.

As a method for depositing a layer from a solution or molten state, it is possible to use a coating method such as a spin coat method, a casting method, a micro gravure coating method, a gravure coating method, a bar coat method, a roll coat method, a wire bar coat method, a dip coat method, a spray coat method, a screen printing method, a flexographic printing method, an offset printing method, an inkjet printing method or the like.

An optimal value of a film thickness of the electron transport layer varies depending on the material to be used, and may be selected such that a driving voltage and a luminous efficiency become moderate values, however, this layer should have at least a thickness which never allows a pinhole to be created, whereas it is not preferable to have a too much thickness because a driving voltage of a device becomes higher. Therefore, a film thickness of the electron transport layer is 1 nm to 1 μm for example, and preferably 2 nm to 500 nm, and more preferably 5 nm to 200 nm.

A charge transport layer provided in contact with an electrode, which has a function of improving an efficiency of injecting charges from the electrode and has an effect of decreasing a driving voltage of a device, is specifically sometimes referred to as a charge injection layer (a hole injection layer, an electron injection layer), in general.

In addition, the above described charge injection layer or an insulating layer having a thickness of 2 nm or less may be provided in contact with an electrode in order to improve the adhesion to the electrode and to improve the charge injection from the electrode, and a thin buffer layer may also be inserted between interfaces of the charge transport layer and the light-emitting layer in order to improve the adhesion of the interfaces or to prevent the mixing and the like.

The order and number of layers to be laminated and a thickness of each layer can be determined appropriately, considering the luminescence efficiency and the life time of the device.

Among the polymer LEDs provided with charge injection layers (electron injection layers, hole injection layers) in the present invention are a polymer LED in which a charge injection layer is provided in contact with a negative electrode, and a polymer LED in which a charge injection layer is provided in contact with a positive electrode.

Specific examples thereof have structures as follows:

e) positive electrode/charge injection layer/light-emitting layer/negative electrode;
f) positive electrode/light-emitting layer/charge injection layer/negative electrode;
g) positive electrode/charge injection layer/light-emitting layer/charge injection layer/negative electrode;
h) positive electrode/charge injection layer/hole transport layer/light-emitting layer/negative electrode;
i) positive electrode/hole transport layer/light-emitting layer/charge injection layer/negative electrode;
j) positive electrode/charge injection layer/hole transport layer/light-emitting layer/charge injection layer/negative electrode;
k) positive electrode/charge injection layer/light-emitting layer/electron transport layer/negative electrode;
l) positive electrode/light-emitting layer/electron transport layer/charge injection layer/negative electrode;
m) positive electrode/charge injection layer/light-emitting layer/electron transport layer/charge injection layer/negative electrode;
n) positive electrode/charge injection layer/hole transport layer/light-emitting layer/electron transport layer/negative electrode;
o) positive electrode/hole transport layer/light-emitting layer/electron transport layer/charge injection layer/negative electrode; and
p) positive electrode/charge injection layer/hole transport layer/light-emitting layer/electron transport layer/charge injection layer/negative electrode.

Among specific examples of the charge injection layers are a layer including conductive polymers, a layer provided between a positive electrode and a hole transport layer which has an ionization potential being an intermediate between a positive electrode material and a hole transport material included in the hole transport layer, and a layer provided between a negative electrode and an electron transport layer which has an electron affinity being an intermediate between a negative electrode material and an electron transport material included in the electron transport layer.

If the above described charge injection layer is a layer which includes a conductive polymer, an electric conductivity of the conductive polymer is preferably 10⁻⁵ S/cm or more and 10³ or less, and is more preferably 10⁻⁵ S/cm or more and 10² or less in order to decrease a leakage current between the light-emitting pixels, and is even more preferably 10⁻⁵ S/cm or more and 10¹ or less.

If the above described charge injection layer is a layer which includes a conductive polymer, an electric conductivity of the conductive polymer is preferably 10⁻⁵ S/cm or more and 10³ S/cm or less, and is more preferably 10⁻⁵ S/cm or more and 10² S/cm or less in order to decrease a leakage current between the light-emitting pixels, and is even more preferably 10⁻⁵ S/cm or more and 10¹ S/cm or less.

The conductive polymer is usually doped with an appropriate amount of ions in order to set the electric conductivity of the conductive polymer at a level of 10⁻⁵ S/cm or more and 10³ or less.

A type of ion to be doped is an anion in the case of the hole injection layer, and a cation in the case of the electron injection layer. Illustrative examples of the anions are polystyrene sulfonic acid ions, alkylbenzene sulfonic acid ions, and camphor sulfonic acid ions, while illustrative examples of the cations are lithium ions, sodium ions, potassium ions, and tetrabutylammonium ions.

A thickness of the charge injection layer is 1 nm to 100 nm for example, and is preferably 2 nm to 50 nm.

Materials used for the charge injection layer may be appropriately selected considering a material used for the electrode or the adjacent layer, and illustrative examples are polyaniline and derivatives thereof, polythiophene and derivatives thereof, polypyrrole and derivatives thereof, polyphenylenevinylene and derivatives thereof, polythienylenevinylene and derivatives thereof, polyquinoline and derivatives thereof, polyquinoxaline and derivatives thereof, conductive polymers such as a polymer having an aromatic amine structure on backbone or side chains thereof, metal phthalocyanine (copper phthalicyanine and the like), and carbons.

The insulating layer having a thickness of 2 nm or less has a function of facilitating the charge injection. Among materials of the above described insulating layer are metal fluorides, metal oxides, organic insulating materials and the like. Among the polymer LEDs provided with the insulating layers as described below having a thickness of 2 nm or less are a polymer LED in which an insulating layer having a thickness of 2 nm or less is provided in contact with the negative electrode and a polymer LED in which an insulating layer having a thickness of 2 nm or less is provided in contact with the positive electrode.

Specific examples thereof have structures as follows:

q) positive electrode/insulating layer having a thickness of 2 nm or less/light-emitting layer/negative electrode;
r) positive electrode/light-emitting layer/insulating layer having a thickness of 2 nm or less/negative electrode;
s) positive electrode/insulating layer having a thickness of 2 nm or less/light-emitting layer/insulating layer having a thickness of 2 nm or less/negative electrode;
t) positive electrode/insulating layer having a thickness of 2 nm or less/hole transport layer/light-emitting layer/negative electrode;
u) positive electrode/hole transport layer/light-emitting layer/insulating layer having a thickness of 2 nm or less/negative electrode;
v) positive electrode/insulating layer having a thickness of 2 nm or less/hole transport layer/light-emitting layer/insulating layer having a thickness of 2 nm or less/negative electrode;
w) positive electrode/insulating layer having a thickness of 2 nm or less/light-emitting layer/electron transport layer/negative electrode;
x) positive electrode/light emitting layer/electron transport layer/insulating layer having a thickness of 2 nm or less/negative electrode;
y) positive electrode/insulating layer having a thickness of 2 nm or less/light emitting layer/electron transport layer/insulating layer having a thickness of 2 nm or less/negative electrode;
z) positive electrode/insulating layer having a thickness of 2 nm or less/hole transport layer/light emitting layer/electron transport layer/negative electrode;
aa) positive electrode/hole transport layer/light-emitting layer/electron transport layer/insulating layer having a thickness of 2 nm or less/negative electrode; and
ab) positive electrode/insulating layer having a thickness of 2 nm or less/hole transport layer/light-emitting layer/electron transport layer/insulating layer having a thickness of 2 nm or less/negative electrode.

A substrate for forming the polymer LED of the present invention may be a material which does not deform during the formation of electrodes and organic layers, and illustrative examples thereof are glass, plastic, a polymer film, and a silicon substrate. When an opaque substrate is used, an opposite electrode is preferably transparent or semi-transparent.

At least one of the positive and negative electrodes included in the polymer LED of the present invention is usually transparent or semi-transparent. The positive electrode side is preferably transparent or semi-transparent.

As a material of the positive electrode, a conductive metal oxide film, a semi-transparent metal thin film or the like is used. Specifically, it is possible to use a film formed by using a conductive glass (NESA) such as indium oxide, zinc oxide, tin oxide, indium tin oxide (ITO) which is a complex thereof, and indium zinc oxide, and further, gold, platinum, silver, copper and the like, and among these materials are preferably ITO, indium zinc oxide, and tin oxide. Examples of the method of fabricating are a vacuum deposition method, a sputtering method, an ion plating method, and a plating method. In addition, organic transparent films such as polyaniline or derivatives thereof and polythiophene or derivatives thereof may be used as the positive electrode.

Although a film thickness of the positive electrode can be appropriately selected considering an optical transmittance and an electric conductivity, the thickness is 10 nm to 10 μm for example, and preferably 20 nm to 1 μm, and more preferably 50 nm to 500 nm.

In addition, it is also possible to provide on the positive electrode a layer having an average thickness of 2 nm or less, such as a layer made from phthalocyanine complexes or conductive polymeric carbons and a layer made from metal oxides, metal fluorides, or organic insulating materials.

As a material of the negative electrode used for the polymer LED of the present invention, a material whose work function is lower is preferable. For example, it is possible to use metals such as lithium, sodium, potassium, rubidium, cesium, beryllium, magnesium, calcium, strontium, barium, aluminum, scandium, vanadium, zinc, yttrium, indium, cerium, samarium, europium, terbium, and ytterbium, or alloys of two or more thereof, or alloys of one or more thereof with one or more of gold, silver, platinum, copper, manganese, titanium, cobalt, nickel, tungsten, and tin, or alternatively graphite or graphite interlayer compounds. Among examples of the alloys are magnesium-silver alloy, magnesium-indium alloy, magnesium-aluminum alloy, indium-silver alloy, lithium-aluminum alloy, lithium-magnesium alloy, lithium-indium alloy, calcium-aluminum alloy and the like. The negative electrode may also be fabricated to have a laminated structure of two or more layers.

Although the film thickness of the negative electrode can be appropriately selected considering an electric conductivity and a durability thereof, and the thickness is 10 nm to 10 μm for example and preferably 20 nm to 1 μm and more preferably 50 nm to 500 nm.

As a method for fabricating the negative electrode, a vacuum deposition method, a sputtering method, a laminating method in which metal thin films are thermally pressed against each other or the like is used. In addition, a layer made from a conductive polymer or a layer having an average thickness of 2 nm or less which is made from metal oxide, metal fluoride, or an organic insulating material may be provided between the negative electrode and the organic layer, or alternatively a protective layer for protecting the polymer LED may be applied after the fabrication of the negative electrode. A protective layer and/or a protective cover is preferably applied for protecting the device from an external environment, in order to stably use the polymer LED for a long time.

As the protective layer, it is possible to use a polymer compound, a metal oxide, a metal fluoride, a metal boride or the like. As the protective cover, it is possible to use a glass plate, a plastic plate whose surface has been treated to have a lower water permeability or the like, and a method in which the cover is laminated to a device substrate by the use of a thermoset resin or a photo-setting resin so as to be sealed is preferably used. By using a spacer for maintaining a space, it becomes easy to prevent the device from being compromised. If an inactive gas such as nitrogen or argon is introduced to the space, the negative electrode can be prevented from being oxidized, and further, if a drying agent such as barium oxide or the like is placed within the space, the device is easily prevented from being damaged by moisture which has been adsorbed during the manufacturing steps. It is preferable to adopt any one or more of the above described solutions.

The polymer LED of the present invention can be used as a planar light source, and as a back light for a segment display device, a dot matrix display device or a liquid crystal display device.

To obtain a planar light emission by using the polymer LED of the present invention, a planar positive electrode may be provided so as to be laminated to a planar negative electrode. Further, there are some methods to obtain a pattern-like light emission, such as a method in which a surface of the planar light emission device is provided with a pattern-like window before using thereof as a mask, a method in which an organic layer at a non-light emission part is deposited to an extremely larger thickness in order to make this layer substantially non-luminescent, or a method in which any one or both of the positive and negative electrodes is formed to a pattern-like shape. Forming a pattern by the use of any one of these methods and then providing some electrodes so as to be operated independently in response to the ON/OFF instructions, it becomes possible to obtain a segment type of display device which can display numbers, characters, simple symbols and the like. Further, in order to obtain a dot matrix device, a positive electrode and a negative electrode each of which has been formed to a stripe shape may be provided perpendicular to each other. Following a method for discriminatingly applying a plurality kind of polymeric fluorescent materials which develop different colors or a method of using a color filter or a fluorescence conversion filter, it becomes possible to achieve a partial color display or a multi-color display. The dot matrix device may be passively driven, or may also actively driven in combination with a TFT or the like. These display devices can be used as a display apparatus of a computer, a television, a portable digital assistance, a portable phone, a car navigator, a view finder of a video camera or the like.

Further, the above described planar light emitting device is of a self-luminous thin type, so that this device an be favorably used as a planar light source for a back light of a liquid crystal display or as a planar light source for an illumination. In addition, by using a flexible substrate, this device can also be used as a curved light source or display apparatus.

Further, the above described polymer compound can be used alone or as a mixture with at least one material selected from a hole transport material, an electron transport material, and a light-emitting material, in order to obtain an organic thin film such as a luminescent thin film, a conductive thin film, or an organic semiconductor thin film. The light-emitting material herein means a thin film, which emits a light by action of heat, electricity, light or the like. The conductive thin film and the organic semiconductor thin film refers to a thin film, whose materials per se or various elements or ions doped therein exhibit a conductive characteristic or a semi-conductive characteristic.

These organic thin films can be used for an organic laser, an organic solar cell, an organic transistor and the like by employing its physical characteristics such as an electric characteristic and an optical characteristic.

The luminescent thin film of the present invention contains the above described polymer compound.

The conductive thin film of the present invention contains the above described polymer compound.

The organic semiconductor thin film of the present invention contains the above described polymer compound.

The composition of the present invention is characterized by comprising the above described polymer compound and at least one material selected from a hole transport material, an electron transport material, and a light-emitting material.

This composition can be used as a light-emitting material or a charge transport material. The composition of the present invention may also contain two or more polymer materials of the present invention.

The polymer compound of the present invention also contains the polymer compound of the present invention and a compound which exhibits phosphorescence.

Although a content ratio of the polymer compound of the present invention and at least one material selected from the hole transport material, the electron transport material, and the light-emitting material may be determined in accordance with a final use thereof, a content ratio which is the same as in the case of the above described light-emitting layer is preferable when this material is used for a light-emitting material.

The solution (ink composition) of the present invention is characterized by containing the above described polymer compound.

The ink composition may only require to have at least one polymer compound, and may also contain an additive such as a hole transport material, an electron transport material, a light-emitting material, a solvent, or a stabilizing agent, other than the polymer compound.

A percentage of the polymer compound in the ink composition is usually 20 wt % to 100 wt %, and preferably 40 wt % to 100 wt % with respect to a total amount of the composition excluding the solvent.

A percentage of the solvent when the solvent is included in the ink composition is usually 1 wt % to 99.9 wt %, and preferably 60 wt % to 99.5 wt %, and more preferably 80 wt % to 99.0 wt % with respect to a total amount of the ink composition.

Although a viscosity of the ink composition varies depending on a printing method to be used, the viscosity at 25° C. is preferably in a range of 1 to 20 mPa·s in order to prevent clogging or flying in a wrong direction at a time of dispensing the ink composition, if the ink composition goes through a dispensing apparatus in an inkjet printing method.

Although a solvent used for the ink composition is not specifically limited, it is preferable to use a solvent which can dissolve or homogeneously disperse materials constituting the ink composition other than the solvent. If the material which constitutes the ink composition is soluble in the non-polar solvent, illustrative examples of the solvents are a chlorine-containing solvent such as chloroform, methylene chloride, or dichloroethane, an ether-based solvent such as tetrahydrofuran, an aromatic hydrocarbon-based solvent such as toluene or xylene, a ketone-based solvent such as acetone or methylethylketone, and an ester-based solvent such as ethyl acetate, butyl acetate, or ethylcellosolveacetate. These solvents can also be used alone or in combination with two or more thereof.

### EXAMPLE

The following are examples for illustrating the present invention in more detail, however, the present invention should not be limited thereto.

As for number-average molecular weight and weight-average molecular weight herein, the number-average molecular weight and the weight-average molecular weight were determined by using chloroform or tetrahydrofuran as a solvent and employing a gel permeation chromatography (GPC) and then reducing to polystyrene.

The weight-average molecular weight was determined by using toluene depending on polymer compounds to be used and employing a light scattering measurement which used a He—Ne laser.

The degree of introduction of boronic acid in the example was determined from an elementary analytical value of carbon, hydrogen, and nitrogen, and from an elementary analytical value of boron obtained by an ICP analysis.

The degree of introduction of boronic acid herein refers to a percentage (%) of the number of moles of boron atoms contained in the polymer compound of the present invention with respect to the number of moles of structures represented by the formula (1) and/or the formula (2) contained in the polymer compound of the present invention.

### Example 1

### Synthesis of 4,7-dibromo-2-phenyl-dihydro-1H-benzo[1,3,2]diazaborole

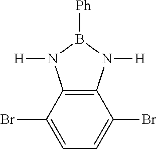

2.57 g of 3,6-dibromo-1,2-phenylenediamine, 1.22 g of phenyl boronic acid, and 50 mL of toluene were placed in a Schlenk tube in an atmosphere of nitrogen, and were refluxed at 120° C. for three days. After completion of the reaction, the solvent was distilled out under a reduced pressure. The residue was dissolved in hexane and then re-crystallized to obtain 2.63 g of white solids.

¹H NMR (300 MHz, DMSO-d6)

σ (ppm)=9.29 (2H), 8.21 (2H), 7.43 (1H), 7.42 (2H), 7.01 (2H)

### Example 2

### Synthesis of Polymer Compound 1

0.53 g of 3,6-dibromo-1,2-phenylenediamine, 1.12 g of 2,7-(1,3,2-dioxaborolan-2-yl)-9,9-dioctylfluorene, and 20 mL of toluene were placed in a Schlenk tube in an atmosphere of nitrogen, and then 40 mg of Pd(PPh₃)₄ was added therein. 10 mL of a 2M solution of potassium carbonate in water was added and then a few drops of Aliquat 336 were added thereto, and heated at 80° C. for three days. After completion of the reaction, the solvent was distilled out under a reduced pressure. The residue was dissolved in a small amount of chloroform and then re-precipitated in methanol. Solids were filtered out and dried under a reduced pressure. An yield of the obtained polymer (hereinafter, referred to as a polymer compound 1) was 0.98 g. A weight-average molecular weight obtained by the light scattering measurement was 3.8×10⁵, and a degree of depolarization was almost zero, and a second virial coefficient A2 was 4.0×10⁴ (cm mol/g²).

Anal. Calcd for (C₃₅H₄₆N₂.0.5H2O)n: C, 83.45; H, 9.40; N, 5.56. Found: C, 83.37; H, 9.50; N, 5.10.

### Example 3

### Synthesis of Polymer Compound 2

0.25 g of the polymer compound 1, 0.06 g of phenyl boronic acid, and 30 mL of toluene were placed in a Schlenk tube in an atmosphere of nitrogen, and then refluxed at 120° C. for three days. After completion of the reaction, the solvent was distilled out under a reduced pressure. The residue was dissolved in a small amount of chloroform and then re-precipitated in methanol. Solids were filtered out and dried under a reduced pressure. An yield of the obtained polymer (hereinafter, referred to as a polymer compound 2) was 0.25 g. A degree of introduction of boronic acid following the ICP measurement was 73%. A polystyrene reduced number-average molecular weight and a polystyrene reduced weight-average molecular weight were respectively Mn=8.6×10³ and Mw=5.5×10⁴.

Anal. Calcd for {(C₃₅H₄₆N₂)_{0.27} (C₄₁H₄₉BN₂)_{0.73} (H₂O)}ₙ: C, 82.19; H, 8.79; N, 4.87. Found: C, 82.19; H, 9.49; N, 4.90.

ICP Calcd: B, 1.37. Found: B, 1.35.

### Example 4

### Synthesis of Polymer Compound 3

0.12 g of the polymer compound 1, 0.04 g of 4-methoxyphenyl boronic acid, and 30 mL of toluene were placed in a Schlenk tube in an atmosphere of nitrogen, and then refluxed at 120° C. for three days. After completion of the reaction, the solvent was distilled out under a reduced pressure. The residue was dissolved in a small amount of chloroform and then re-precipitated in methanol. Solids were filtered out and dried under a reduced pressure. An yield of the obtained polymer (hereinafter, referred to as a polymer compound 3) was 0.12 g. A degree of introduction of boronic acid following the ICP measurement was 82%. A polystyrene reduced number-average molecular weight and a polystyrene reduced weight-average molecular weight were respectively Mn=3.1×10³ and Mw=7.0×10³.

Anal. Calcd for {(C₃₅H₄₆N₂)_{0.18} (C₄₂H₅₁BN₂O)_{0.82} (2.5H₂O)}ₙ: C, 77.08; H, 8.75; N, 4.41. Found: C, 77.39; H, 8.65; N, 4.15.

ICP Calcd: B, 1.40. Found: B, 1.44.

### Example 5

### Synthesis of Polymer Compound 4

0.25 g of the polymer compound 1, 0.09 g of 4-butylphenyl boronic acid, and 30 mL of toluene were placed in a Schlenk tube in an atmosphere of nitrogen, and then refluxed at 120° C. for three days. After completion of the reaction, the solvent was distilled out under a reduced pressure. The residue was dissolved in a small amount of chloroform and then re-precipitated in methanol. Solids were filtered out and dried under a reduced pressure. An yield of the obtained polymer (hereinafter, referred to as a polymer compound 4) was 0.30 g. A degree of introduction of boronic acid following the ICP measurement was 85%. A polystyrene reduced number-average molecular weight and a polystyrene reduced weight-average molecular weight were respectively Mn=9.8×10³ and Mw=8.1×10⁴.

Anal. Calcd for {(C₃₅H₄₆N₂)_{0.15} (C₄₂H₅₁BN₂)_{0.85} (1.2H₂O)}ₙ: C, 82.01; H, 9.14; N, 4.40. Found: C, 81.43; H, 9.11; N, 4.74.

ICP Calcd: B, 1.44. Found: B, 1.44.

### Example 6

### Evaluations on UV-Visible Absorption Characteristic and Fluorescent Characteristic of Solution

Evaluation of an UV-visible absorption characteristic of the polymer compounds 2 to 4 was performed by preparing a solution of a sample in chloroform, transferring the solution into a rectangular quartz cell having a size of 1 cm×1 cm, and then using a spectrophotometer (manufactured by Shimadzu Corporation, UV-2550).

Evaluation of a fluorescent characteristic was performed by preparing a solution of a sample in chloroform, transferring the solution into a rectangular tetrahedral quartz cell having a size of 1 cm×1 cm, and then measuring the solution at an excitation wavelength of 355 nm by using a fluorescence spectrophotometer (F-4010) manufactured by Hitachi.

The obtained UV-visible absorption peak wavelength and fluorescent peak wavelength are shown in Table 1.

TABLE 1

| | UV-visible | |
|---|---|---|
| | absorption peak | Fluorescent peak |
| Polymer compound | wavelength (nm) | wavelength (nm) |
| Polymer compound 2 <Example 3> | 360 | 407 |
| Polymer compound 3 <Example 4> | 354 | 409 |
| Polymer compound 4 <Example 5> | 360 | 420 |

### Example 7

### Evaluation on Fluorescent Characteristic of Thin Film

Evaluation of a fluorescent characteristic of the thin film was performed by preparing a 0.8 wt % solution of a sample in toluene, spin-coating the solution on a quartz plate to form a thin film of a polymer compound, and then subjecting the sample thus obtained to a fluorescence spectrophotometer (manufactured by JOBINYVON-SPEX Co.) which uses an excitation wavelength of 350 nm. The polymer compound 3 was confirmed to have the strongest fluorescent peak wavelength at 413 nm.

### Example 8

### Synthesis of Polymer Compound 5

Added to a 200 ml separable flask, to which a Dimroth condenser was connected, were 2.39 g of ethyleneglycol 9,9-dioctylfluorene-2,7-diborate ester, 1.97 g of 9,9-dioctyl-2,7-dibromofluorene, 0.24 g of 3,6-dibromo-1,2-phenylenediamine, 0.59 g of Aliquat 336, and 45 ml of toluene. 3.2 mg of bis(triphenylphosphine) palladium (II) dichloride was added thereto in an atmosphere of nitrogen and was heated to 85° C. This solvent was heated to 105° C. while adding 12.3 g of a 17.5 wt % aqueous solution of sodium carbonate dropwise, followed by stirring the mixture for 12 hours. After removing an aqueous layer, 2.07 g of sodium N,N-diethyldithiocarbamate trihydrate and 27 mL of an ion-exchange water were added thereto and stirred for 2 hours at 65° C. After separating an organic layer from an aqueous layer, about 60 mL of an ion-exchange water was used to rinse two times, The organic layer was added dropwise to about 700 mL of methanol to allow a polymer to be precipitated, and then the precipitate was filtered before being dried, and consequently 2.57 g of polymer (referred to as a polymer compound 5, hereinafter) was obtained. A polystyrene reduced number-average molecular weight and a polystyrene reduced weight-average molecular weight were Mn=1.0×10⁴ and Mw=1.9×10⁴ respectively.

### Example 9

### Evaluations on UV-Visible Absorption Characteristic and Fluorescent Characteristic of Solution

Evaluation of an UV-visible absorption characteristic of the polymer compound 5 was performed by preparing a toluene solution as a sample, transferring the solution into a rectangular quartz cell having a size of 1 cm×1 cm, and then subjecting the solution to a spectrophotometer (manufactured by Varian Corp., Cary5E). The polymer compound 5 was confirmed to have the strongest UV-visible absorption peak wavelength at 380 nm.

Evaluation of a fluorescent characteristic of the polymer compound 5 was performed by preparing a toluene solution as a sample, transferring the solution into a rectangular tetrahedral quartz cell having a size of 1 cm×1 cm, and then measuring the solution at an excitation wavelength of 350 nm by using a fluorescence spectrophotometer (manufactured by JOBINYVON-SPEX Corp. Fluorolog).

The polymer compound 5 was confirmed to have the strongest fluorescent peak wavelength at 414 nm.

### Example 10

### Evaluation on Fluorescent Characteristic of Thin Film

Evaluation of a fluorescent characteristic of the thin film was performed by preparing a 0.8 wt % solution of a sample in toluene, spin-coating the solution on a quartz plate to form a thin film of a polymer compound, and then subjecting the sample thus obtained to a fluorescence spectrophotometer (manufactured by JOBINYVON-SPEX Corp., Fluorolog) which uses an excitation wavelength of 350 nm. The polymer compound 5 was confirmed to have the strongest fluorescent peak wavelength at 421 nm.

### Synthesis Example 1

### Synthesis of Polymer Compound 6

Added to a 200 mL three-necked round flask, to which a Dimroth condenser was connected, were 1.59 g of 2,7-(1,3,2-dioxaborolan-2-yl) 9,9-dioctylfluorene, 1.38 g of bis(4-bromophenyl)-4-sec-butylaniline, and 23 ml of toluene. The monomer solution was heated in an atmosphere of nitrogen, and then 1.2 mg of palladium acetate, 9.5 mg of tris(2-methoxyphenyl)phosphine, and 10.2 g of a 20 wt % aqueous solution of tetraethylammonium hydroxide were poured at 50° C. After heating the solution to 105° C., stirred for 4 hours. Subsequently, 267 mg of t-butylphenyl boronic acid dissolved in 1.5 mL of toluene was added thereto and stirred for 2 hours at 105° C. Further, 0.6 g of sodium N,N-diethyldithiocarbamate trihydrate and 9 mL of an ion-exchange water were added thereto, and stirred for 2 hours at 65° C. After separating an organic layer from an aqueous layer, the organic layer was rinsed with about 70 mL of a 2M hydrochloric acid (once), about 70 mL of a 10 wt % aqueous solution of sodium acetate (once), and about 70 mL of an ion-exchange water (three times) in this order. The organic layer was added dropwise to about 800 mL of methanol to allow a polymer to be precipitated, and then the precipitate was filtered before being dried to yield solids. The solids were dissolved in about 90 mL of toluene, and this solution was allowed to pass through a silica gel/alumina column, through which toluene was previously passed, and then the solution was added dropwise to about 800 mL of methanol to allow a polymer to be precipitated, and the precipitate was filtered before being dried, and consequently, 1.92 g of polymer was obtained (referred to as a polymer compound 6, hereinafter). A weight-average molecular weight calculated in terms of polystyrene was Mw=3.0×10⁵.

### Example 11

### Preparation of Solution

The polymer compound 3 obtained as described above was dissolved in toluene to prepare a toluene solution whose polymer concentration was 1.5 wt %.

### Fabrication of EL Device

On a glass substrate to which an ITO film having a thickness of 150 nm was deposited by a sputtering method, a suspension of poly(3,4)ethylenedioxythiophene/polystyrene sulfonic acid (produced by Bayer, BaytronP AI4083) being filtered through a 0.2 μm membrane filter was spin-coated to a thickness of 70 nm in order to form a thin film, and the thin film thus formed was dried on a hot plate at 200° C. for 10 minutes. Subsequently, the toluene solution obtained as described above was used to form a film, at a rotational speed of 1400 rpm by spin coating. The film thickness after being formed was 140 nm. In addition, after drying this film at 80° C. under the reduced pressure for one hour, lithium fluoride was vapor-deposited to a thickness of about 4 nm, and calcium was vapor-deposited to a thickness of about 5 nm as a negative electrode, and then aluminum was vapor-deposited to a thickness of about 80 nm in order to fabricate an EL device. Metal vapor-deposition was allowed to start, after a degree of vacuum reached to a level of 1×10⁴ Pa or less.

### Performance of EL Device

A voltage was applied to the device thus obtained, and then a current was confirmed to be supplied. A current density at an applied voltage of 12.0 V was about 7 mA/cm².

### Example 12

### Preparation of Solution

The polymer compound 5 obtained as described above was dissolved in xylene to prepare a xylene solution whose polymer concentration was 2.5 wt %. In addition, the polymer compound 6 obtained as described above was dissolved in xylene to prepare a xylene solution whose polymer concentration was 0.5 wt %.

### Fabrication of EL Device

On a glass substrate to which an ITO film having a thickness of 150 nm was deposited by a sputtering method, a suspension of poly(3,4)ethylenedioxythiophene/polystyrene sulfonic acid (produced by Bayer, BaytronP AI4083) being filtered through a 0.2 μm membrane filter was spin-coated to a thickness of 70 nm in order to form a thin film, and the thin film thus formed was dried on a hot plate at 200° C. for 10 minutes. Subsequently, a solution of the polymer compound 6 in xylene obtained as described above was used to form a hole transport layer, at a rotational speed of 3000 rpm by spin coating. The film thickness after being formed was about 10 nm. This film was heat-treated on a hot plate at 180° C. for 15 minutes under a nitrogen gas stream in a glove box. Subsequently, the solution of the polymer compound 5 in xylene obtained as described above was used to form a film at a rotational speed of 1000 rpm by spin-coating. The film thickness after being formed was about 130 nm. This film was heat-treated on a hot plate at 130° C. for 20 minutes under a nitrogen gas stream in a glove box. Then, barium was vapor-deposited to a thickness of about 5 nm as negative electrode, and then aluminum was vapor-deposited to a thickness of about 80 nm in order to fabricate an EL device. Metal vapor-deposition was allowed to start, after a degree of vacuum reached to a level of 1×10⁴ Pa or less.

### Performance of EL Device

A voltage was applied to the device thus obtained, and then an EL luminescence having its peak at 425 nm and 520 nm was obtained from this device. A luminescence intensity at an applied voltage of 6.0 V was 79 cd/m², and a color of the EL luminescence was x=0.25 and y=0.38 when being represented by a C.I.E. color coordinate. The intensity of the EL luminescence was almost proportional to a current density. In addition, a current density at an applied voltage of 6.0 V was 8.2 mA/cm². The device had begun to exhibit the luminescence at 4.4 V, and the maximum luminescence efficiency was 1.1 cd/A.

A polymeric light-emitting device according to the present invention, which has a layer comprising a polymer compound having a structure represented by the above described formula (1) as a repeating unit between electrodes consisting of a positive electrode and a negative electrode, can be used for a planar light source, a segment display device, a dot matrix display device, a liquid crystal display device and the like.

1. A polymer compound comprising a structure represented by a formula (1) as described below: 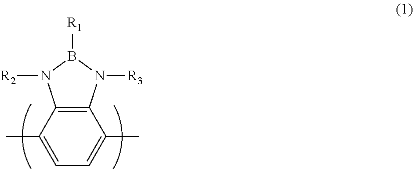
wherein R₁, R₂, and R₃ each independently represents a hydrogen atom or a substituent.

2. The polymer compound according to claim 1, further comprising repeating units represented by formulas (5), (6), (7), or (8) as described below:
—Ar₁— (5),
—(—Ar₂—X₁—)_{ff}—Ar₃— (6),
—Ar₄—X₂— (7), and
—X₃— (8)
wherein Ar₁, Ar₂, Ar₃, and Ar₄ each independently represent an arylene group, a divalent heterocyclic group, or a divalent group having a metal complex structure;
X₁, X₂, and X₃ each independently represent —CR₉═CR₁₀—, —C≡C—, —N(R₁₁)—, or —(SiR₂₂R₂₃)ₘ—;
R₉ and R₁₀ each independently represent a hydrogen atom, an alkyl group, an aryl group, a monovalent heterocyclic group, a carboxyl group, a substituted carboxyl group, or a cyano group;
R₁₁, R₁₂, and R₁₃ each independently represent a hydrogen atom, an alkyl group, an aryl group, a monovalent heterocyclic group, an arylalkyl group, or a substituted amino group;
ff represents 1 or 2; and
m represents an integer from 1 to 12,
provided that when each of R₉, R₁₀, R₁₁, R₁₂, and R₁₃ is present in a plural number, they may be or may not be the same.

3. The polymer compound according to claim 1, wherein the polymer compound has a weight-average molecular weight of 10³ to 10⁸ in terms of polystyrene.

4. A method for producing the polymer compound according to claim 1, comprising the step of performing polymerization of a compound represented by formula (A) described below: 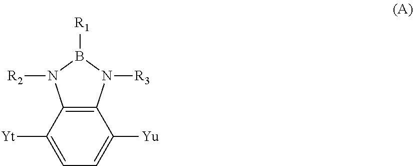
wherein Yₜ and Yᵤ each independently represent a substituent involved in the polymerization; and
wherein R₁, R₂, and R₃ each independently represents a hydrogen atom or a substituent.

5. The method according to claim 4, wherein Yₜ and Yᵤ are independently selected from the group consisting of a halogen atom, an alkyl sulfonate group, an aryl sulfonate group, and an arylalkyl sulfonate group, and the polymerization is performed in the presence of a nickel compound or a palladium catalyst.

6. A compound represented by the formula (A) of claim 4.

7. A method for producing the compound according to claim 6, comprising reacting a compound represented by formula (B) described below with a compound represented by formula (C) described below: 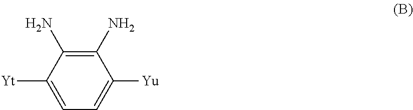
wherein Yₜ and Yᵤ each independently represent a substituent; and 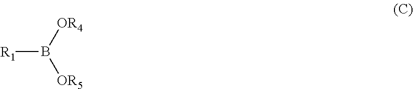
wherein R₁ represents a hydrogen atom or a substituent, R₄ and R₅ each independently represent a hydrogen atom or a substituent, or R₄ and R₅ together form a ring.

8. A method for producing the polymer compound according to claim 1, comprising reacting a polymer compound containing a structure represented by formula (2) described below with the compound represented by formula (C) of claim 7.

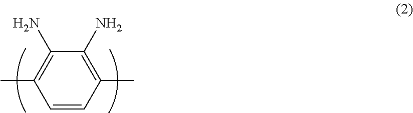

9. A polymer compound comprising a structure represented by formula (2) of claim 8.

10. The polymer compound according to claim 9, further comprising repeating units represented by formulas (5), (6), (7), or (8) of claim 2.

11. The polymer compound according to claim 9, wherein the polymer compound has a polystyrene reduced weight-average molecular weight of 10³ to 10⁸ in terms of polystyrene.

12. A method for producing the polymer compound according to claim 9, comprising performing polymerization of the compound represented by formula (B) described above.

13. A composition comprising at least one material selected from the group consisting of a hole transport material, an electron transport material, and a light-emitting material, and at least one polymer compound according to claim 1.

14. A composition comprising the polymer compound according to claim 1, and a compound which can emit phosphorescence.

15. A composition comprising at least two polymer compounds according to claim 1.

16. A solution comprising the polymer compound according to claim 1.

17. A solution comprising the composition according to claim 13.

18. The solution according to claim 16, comprising two or more organic solvents.

19. The solution according to claim 16, wherein the solution has a viscosity of 1 to 20 mPa·s at 25° C.

20. A luminescent thin film comprising the polymer compound according to claim 1.

21. The luminescent thin film according to claim 20, which has a luminescent quantum yield of 50% or more.

22. A conductive thin film comprising the polymer compound according to claim 1.

23. An organic semiconductor thin film comprising the polymer compound according to claim 1.

24. An organic transistor comprising the organic semiconductor thin film according to claim 23.

25. A method for forming the thin film according to claim 20, which comprises using an inkjet printing method.

26. A polymer light-emitting device having an organic layer between a positive electrode and a negative electrode, wherein the organic layer comprises the polymer compound according to claim 1.

27. The polymer light-emitting device according to claim 26, wherein the organic layer is a light-emitting layer.

28. The polymer light-emitting device according to claim 26, wherein the light-emitting layer further comprises a hole transport material, an electron transport material, or a light-emitting material.

29. The polymer light-emitting device according to claim 26 having a light-emitting layer and a charge transport layer between electrodes consisting of a positive electrode and a negative electrode, wherein the charge transport layer comprises the polymer compound of claim 1.

30. The polymer light-emitting device according to claim 26 having a light-emitting layer and a charge transport layer between electrodes consisting of a positive electrode and a negative electrode, and having a charge injection layer between the charge transport layer and the electrode, wherein the charge injection layer comprises the polymer compound of claim 1.

31. A planar light source, comprising the polymer light-emitting device according claim 26.

32. A segment display device, comprising the polymer light-emitting device according to any one of claims 26 to 30.

33. A dot matrix display device, comprising the polymer light-emitting device according to claim 26.

34. A liquid crystal display device, having the polymer light-emitting device according to claim 26 as a back light.

35. A polymer light-emitting device having an organic layer between a positive electrode and a negative electrode, wherein the organic layer comprises the polymer composition according to claim 13.

36. The polymer light-emitting device according to claim 26 having a light-emitting layer and a charge transport layer between electrodes consisting of a positive electrode and a negative electrode, wherein the charge transport layer comprises the polymer composition of claim 13.

37. The polymer light-emitting device according to claim 26 having a light-emitting layer and a charge transport layer between electrodes consisting of a positive electrode and a negative electrode, and having a charge injection layer between the charge transport layer and the electrode, wherein the charge injection layer comprises the polymer composition of claim 13.
